(19) United States
(12) Patent Application Publication
(10) Pub. No.: US 2011/0001112 A1
(43) Pub. Date: Jan. 6, 2011

(54) NONVOLATILE MEMORY DEVICE AND MANUFACTURING METHOD THEREOF

(76) Inventor: Masahiro KIYOTOSHI, Mie (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/686,715

(22) Filed: Jan. 13, 2010

(30) Foreign Application Priority Data
Jul. 3, 2009 (JP) 2009-159166

(51) Int. Cl. H01L 45/00; H01L 29/18; H01L 29/22; H01L 21/283; H01L 21/20

(52) U.S. Cl. 257/3; 257/42; 257/43; 438/694; 438/478; 257/E45.002; 257/E29.087; 257/E29.094; 257/E21.159; 257/E21.09

(57) ABSTRACT

A nonvolatile memory device according to an embodiment of the present invention includes a first wire that extends in a first direction, a second wire that is formed at a height different from the first wire and extends in a second direction, and a nonvolatile memory cell that is arranged to be sandwiched between the first wire and the second wire at a position at which the first wire and the second wire intersect with each other. The nonvolatile memory cell includes a structure in which a nonvolatile storage element is sandwiched by semiconductor layers having different polarities.

### CROSS-REFERENCE TO RELATED APPLICATIONS

This application is based upon and claims the benefit of priority from the prior Japanese Patent Application No. 2009-159166, filed on Jul. 3, 2009; the entire contents of which are incorporated herein by reference.

### BACKGROUND OF THE INVENTION

1. Field of the Invention

The present invention relates to a nonvolatile memory device and a manufacturing method thereof.

2. Description of the Related Art

A nonvolatile memory represented by a NAND-type flash memory is widely used as a large-capacity data storage in a cell phone, a digital still camera, a universal serial bus (USB) memory, a silicon-audio, and the like, and the market thereof is further expanding because of the reduction of the manufacturing cost per bit due to the extreme scaling. However, the NAND-type flash memory utilizes an operation of a transistor that records data by the threshold shift and it is said that there is a limitation in high uniformity, high reliability, high-speed operation, and high integration of transistor characteristics for further scaling in the future. Therefore, a new type of nonvolatile memory is required.

Examples of a nonvolatile memory to meet such a demand include a phase-change memory (PCM) element and a resistive random access memory (ReRAM) element. The phase-change memory element and the resistive random access memory element operate by utilizing a variable resistance state of a resistant material, so that the operation of a transistor is not needed in writing and erasing. Moreover, the element characteristics improve as the size of the resistant material is shrunk.

The resistive random access memory is configured by arranging variable resistive elements in an array at intersections of a plurality of word lines that extend in parallel with a first direction and a plurality of bit lines that extend in parallel with a second direction. Moreover, unlike the conventional NAND-type flash memory, the resistive random access memory performs the sensing based on an amount of current, so that a rectifier element (diode) for regulating a direction of current from the word line to the bit line is provided in series with the variable resistive element of each memory cell (for example, see Japanese Patent Application Laid-open No. 2004-6579).

A PIN diode that typically realizes excellent rectifying characteristics can be used as the rectifier element. However, when the PIN diode is used, the thickness of an intrinsic semiconductor layer (I layer) needs to be 100 nm or more for ensuring a reverse breakdown voltage according to Japanese Patent Application Laid-open No. 2004-6579. Therefore, there is a limitation in suppressing the height of the rectifier element. When memory cells employing the PIN diode are three-dimensionally stacked, the height of the stacked memory cells inevitably becomes extremely large in accordance with the height of the rectifier element, so that the micro-patterning becomes difficult. Specifically, when the feature size of such a stacked memory is scaled, the height of the rectifier element needs to be maintained for the height of the I layer for keeping the rectifying characteristics of the rectifier element, so that the aspect ratio in processing the rectifier element becomes too large. Consequently, the processing becomes more difficult and a pattern collapse and a pattern bending are easy to occur.

### BRIEF SUMMARY OF THE INVENTION

A nonvolatile memory device according to an embodiment of the present invention comprises: a first wire that extends in a first direction; a second wire that is formed at a height different from the first wire and extends in a second direction; and a nonvolatile memory cell that is arranged to be sandwiched between the first wire and the second wire at a position at which the first wire and the second wire intersect with each other, wherein the nonvolatile memory cell includes a structure in which a nonvolatile storage element is sandwiched by semiconductor layers having different polarities.

A method of manufacturing a nonvolatile memory device according to an embodiment of the present invention comprises: forming a stacked film that includes a structure in which a nonvolatile memory layer is sandwiched by semiconductor layers having different polarities above a substrate; and etching the stacked film by using a dry etching method so that a memory cell array, in which memory cells each including a structure in which the nonvolatile memory layer is sandwiched by the semiconductor layers having different polarities are two-dimensionally arranged at respective intersection positions of a plurality of first wires that extends in a predetermined direction and a plurality of second wires that extends in a direction intersecting with the predetermined direction, is formed.

### BRIEF DESCRIPTION OF THE DRAWINGS

FIG. 1A is a diagram illustrating an example of a cell structure of a nonvolatile memory device according to a first embodiment;

FIGS. 1B and 1C are diagrams each illustrating an example of a circuit diagram of the nonvolatile memory device according to the first embodiment;

FIG. 2A is a diagram illustrating a cell structure of a typical nonvolatile memory device, and FIG. 2B is a circuit diagram of the typical nonvolatile memory device;

FIG. 3 is a diagram illustrating an example of a memory cell array structure of the nonvolatile memory device;

FIG. 4A is a circuit diagram illustrating an applied bias voltage state to word lines and bit lines in a selected/non-selected state, FIG. 4B is an energy band diagram of a non-selected cell of a resistive random access memory cell according to the first embodiment, FIG. 4C is an energy band diagram of a selected cell of the same, FIG. 4D is an energy band diagram of a non-selected cell of a resistive random access memory cell in a comparison example, and FIG. 4E is an energy band diagram of a selected cell of the same;

FIG. 5A is an energy band diagram of the non-selected cell of the resistive random access memory cell according to the first embodiment, FIG. 5B is an energy band diagram of the selected cell of the same, FIG. 5C is an energy band diagram of the non-selected cell of the resistive random access memory cell in the comparison example, and FIG. 5D is an energy band diagram of the selected cell of the same;

FIG. 6A is a circuit diagram illustrating an applied bias voltage state to the word lines and the bit lines in a selected/non-selected state, FIG. 6B is a band diagram of the non-selected cell in the early state of writing of the resistive random access memory cell according to the first embodiment, FIG. 6C is a band diagram of the selected cell of the same, FIG. 6D is a band diagram of the non-selected cell in the early state of the writing of the resistive random access memory cell in the comparison example, and FIG. 6E is a band diagram of the selected cell of the same;

FIG. 7A is a circuit diagram illustrating a voltage application state to the word lines and the bit lines in a selected/non-selected state, FIG. 7B is an energy band diagram of the non-selected cell in the early state of erasing of the resistive random access memory cell according to the first embodiment, FIG. 7C is a band diagram of the selected cell of the same, FIG. 7D is an energy band diagram of the non-selected cell in the early state of the erasing of the resistive random access memory cell in the comparison example, and FIG. 7E is an energy band diagram of the selected cell of the same;

FIG. 8 is a diagram illustrating an example of a band diagram when a Schottky barrier of each semiconductor layer is formed on a wire side;

FIGS. 9A to 9H are cross-sectional views in a direction vertical to an extending direction (X direction) of the word line, schematically illustrating an example of a procedure of a manufacturing method of the nonvolatile memory device according to the first embodiment;

FIGS. 10A to 10H are cross-sectional views in a direction parallel to the extending direction of the word line, schematically illustrating an example of a procedure of the manufacturing method of the nonvolatile memory device according to the first embodiment;

FIGS. 11A to 11F are cross-sectional views in a direction vertical to the extending direction (X direction) of the word line, schematically illustrating an example of a procedure of a manufacturing method of a nonvolatile memory device according to a second embodiment;

FIGS. 12A to 12F are cross-sectional views in a direction parallel to the extending direction of the word line, schematically illustrating an example of a procedure of the manufacturing method of the nonvolatile memory device according to the second embodiment;

FIGS. 13A to 13F are cross-sectional views in a direction vertical to the extending direction (X direction) of the word line, schematically illustrating an example of a procedure of a manufacturing method of a nonvolatile memory device according to a third embodiment; and

FIGS. 14A to 14F are cross-sectional views in a direction parallel to the extending direction of the word line, schematically illustrating an example of a procedure of the manufacturing method of the nonvolatile memory device according to the third embodiment.

### DETAILED DESCRIPTION OF THE INVENTION

A nonvolatile memory device according to embodiments of the present invention is explained in detail below with reference to the accompanying drawings. The present invention is not limited to these embodiments. It should be noted that the cross-sectional views of the nonvolatile memory device used in the following embodiments are schematic and a relation between the thickness and the width of a layer, a ratio of the thicknesses of respective layers, and the like may be different from realistic ones. Furthermore, the film thickness in the following is only an example and is not limited thereto. Moreover, in the following, a resistive random access memory is explained as an example of the nonvolatile memory device.

### First Embodiment

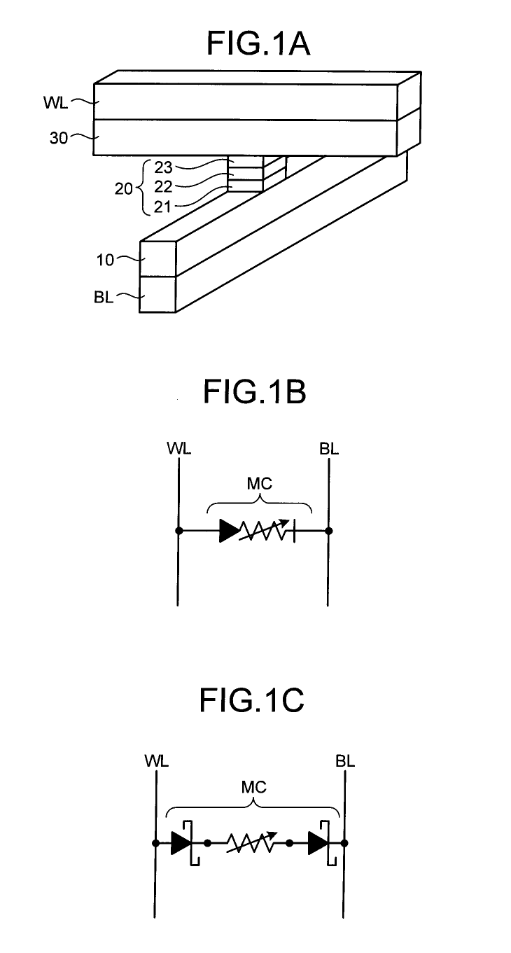

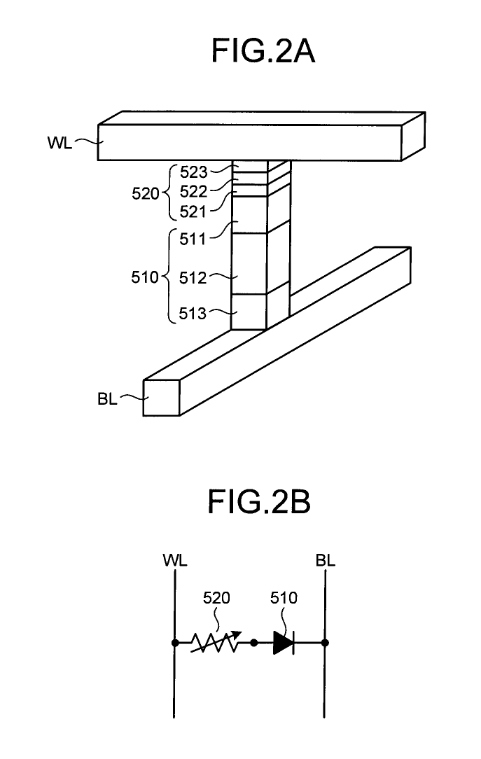

FIG. 1A is a diagram illustrating an example of a cell structure of a nonvolatile memory device according to the first embodiment, FIGS. 1B and 1C are diagrams each illustrating an example of a circuit diagram of the nonvolatile memory device according to the first embodiment, FIG. 2A is a diagram illustrating a cell structure of a typical nonvolatile memory device, and FIG. 2B is a circuit diagram of the typical nonvolatile memory device. First, as shown in FIG. 2A, in the typical nonvolatile memory device, a memory cell, in which a rectifier element 510 composed of a PIN diode in which a P-type semiconductor layer 511, an I-type (intrinsic) semiconductor layer (hereinafter, I layer) 512, and an N-type semiconductor layer 513 are laminated, and a variable resistive element 520 composed of a variable resistive layer 522 sandwiched by upper and lower electrodes 521 and 523 are stacked, is formed at an intersection of a first wire (bit line) BL that extends in a first direction and a second wire (word line) WL that extends in a second direction. FIG. 2B illustrates a circuit diagram of a structure of the memory cell shown in FIG. 2A in which the variable resistive element 520 and the rectifier element 510 are connected in series. In the nonvolatile memory device having such a structure, the thickness of the I layer 512 needs to be 100 nm or more for ensuring a reverse breakdown voltage as described in Japanese Patent Application Laid-open No. 2004-6579. Therefore, the height of the stacked element structure tends to be large.

On the other hand, as shown in FIG. 1A, in the nonvolatile memory device in the first embodiment, the first wire (bit line) BL on the upper surface of which an N-type semiconductor layer 10 is formed and which extends in the first direction and the second wire (word line) WL on the lower surface of which a P-type semiconductor layer 30 is formed and which extends in the second direction are formed, and a variable resistive element 20 composed of a variable resistive layer 22 sandwiched by upper and lower electrodes 21 and 23 is formed at the intersection of the semiconductor layers having different polarities. Ohmic contacts are formed on the first wire BL side of the N-type semiconductor layer 10 and the second wire WL side of the P-type semiconductor layer 30. Moreover, a Schottky barriers are preferably formed on the variable resistive element 20 sides of the N-type semiconductor layer 10 and the P-type semiconductor layer 30. Therefore, an electrode material is selected to form such junctions. A memory cell (nonvolatile memory cell) MC is formed with the N-type semiconductor layer 10, the variable resistive element 20, and the P-type semiconductor layer 30. Moreover, at least one of the N-type semiconductor layer 10 and the P-type semiconductor layer 30 preferably has a plate-like shape similar to the first wire BL and the second wire WL. In the example shown in FIGS. 1A to 1C, the first wire BL and the N-type semiconductor layer 10 are collectively processed and the second wire WL and the P-type semiconductor layer 30 are collectively processed, so that both of the N-type semiconductor layer 10 and the P-type semiconductor layer 30 have a plate-like shape. The N-type semiconductor layer 10 or the P-type semiconductor layer 30 is processed into the plate-like shape, so that the cross section area thereof becomes large, enabling to suppress a series resistance even when the density of impurities to be introduced is decreased. Moreover, a depletion layer can be formed at interfaces on the sides of the variable resistive element 20 by decreasing the concentration of impurities.

In the memory cell MC having such a structure, a PN junction is formed by sandwiching the thin variable resistive element 20 with the thickness of about 20 nm between the N-type semiconductor layer 10 and the P-type semiconductor layer 30 to have a rectification behavior. Moreover, the N-type and P-type semiconductor layers 10 and 30 and the first and second wires BL and WL are formed so that the Schottky barrier is formed on the sides of the variable resistive element 20 and the ohmic contact is formed on the sides of the first and second wires BL and WL, thereby having the rectification property. The circuit diagram having the structure shown in FIG. 1A is illustrated as FIG. 1B in which the variable resistive element 20 and the rectifier element are integrated or FIG. 1C in which a Schottky diode is formed on both sides of the variable resistive element 20.

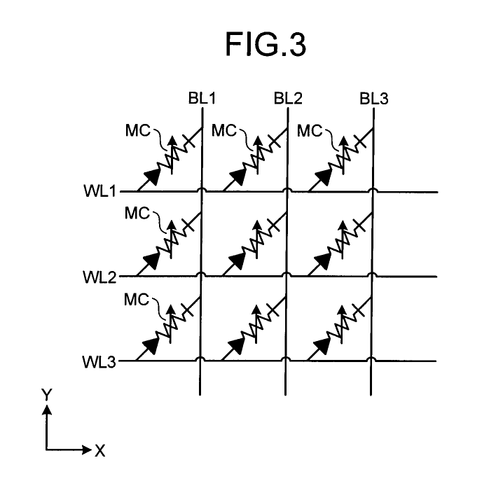

The memory cells each having the structure as shown in FIGS. 1A to 1C are two-dimensionally arranged to configure the nonvolatile memory device. FIG. 3 is a diagram illustrating an example of a memory cell array structure of the nonvolatile memory device. In FIG. 3, a right and left direction on a paper drawing is an X direction and a direction vertical to the X direction on the paper drawing is a Y direction. A plurality of bit lines BLi (i=1, 2, 3, . . . ) as the first wires that extend in parallel with the Y direction (column direction) and a plurality of word lines WLj (j=1, 2, 3, . . . ) as the second wires that extend in parallel with the X direction (row direction) at a height different from the bit lines BLi are arranged to intersect with each other, and the resistive random access memory cell MC having a structure in which the variable resistive element is sandwiched between the semiconductor layers having different polarities is arranged at each intersection.

A plurality of the resistive random access memory cells MC can be stacked in a direction vertical to both of the X direction and the Y direction. In this case, as described later, the wires are formed so that the word line WLj or the bit line BLi is shared by the resistive random access memory cells MC on the upper and lower layers and the directions of the word line WLj and the bit line BLi sandwiching the resistive random access memory cell MC in an up and down direction are orthogonal to each other.

Next, the operation of the nonvolatile memory device having such a structure is explained by using an energy band model. In the resistive random access memory, in the initialization process by high-voltage application called forming, a low resistance portion called filament to be a path for electrical conduction is generated. Then, the filament can be reset to a high resistance state by charge-up or melting by controlling the current to flow in the filament or can be set to a state of recovering to the conduction state by controlling the current to flow in the filament again. Generally, the relationship V_{form}>Vₛₑₜ>Vᵣₑₛₑₜ is satisfied, in which V_{form} is a voltage applied at the time of the forming, Vₛₑₜ is a voltage applied at the time of the setting, and Vᵣₑₛₑₜ is a voltage applied at the time of the resetting. In the following explanation, the band gap changes in a model according to the conduction of the filament. For example, the model is expressed such that the band gap expands in the “reset” and shrinks in the “set” or the “forming”. Moreover, in the following drawings, the operation of the memory cell of the resistive random access memory in which a typical PIN diode and the variable resistive element are combined (stacked) is also illustrated as a comparison example.

### <In Forming>

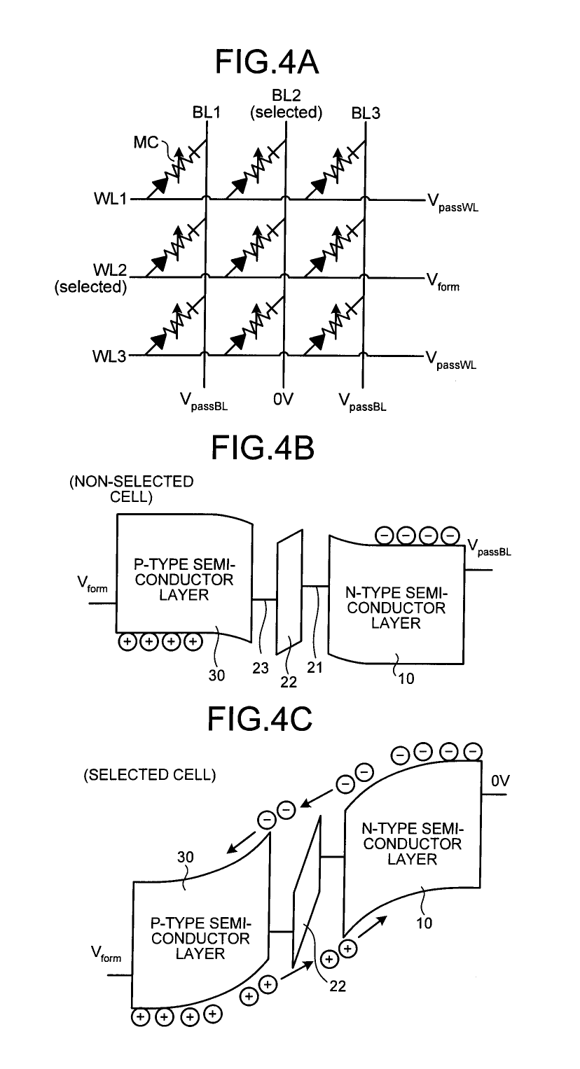

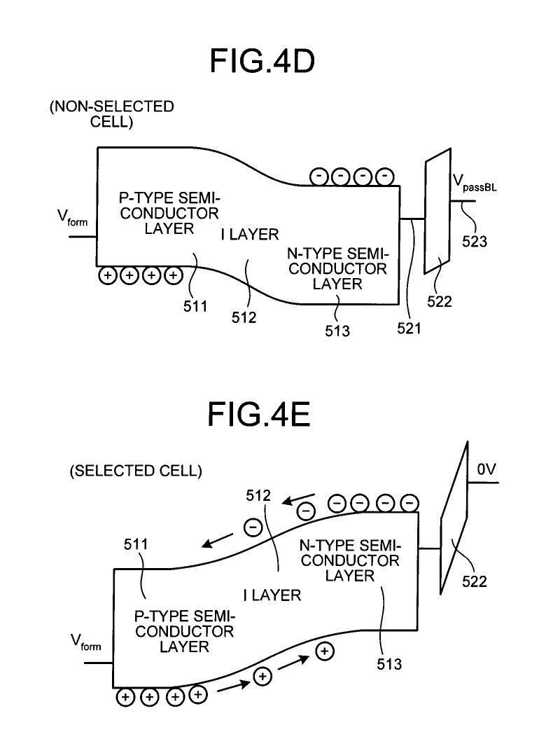

FIGS. 4A to 4E are diagrams each schematically illustrating the state of the resistive random access memory cell at the time of the forming. Specifically, FIG. 4A is a circuit diagram illustrating an applied bias voltage state to the word lines and the bit lines in a selected/non-selected state, FIG. 4B is a band diagram of a non-selected cell of the resistive random access memory cell according to the first embodiment, and FIG. 4C is a band diagram of a selected cell of the same. FIG. 4D is a band diagram of a non-selected cell of a resistive random access memory cell in the comparison example, and FIG. 4E is a band diagram of a selected cell of the same. In the band diagrams, a portion corresponding to a metal film (such as the electrodes 21 and 23 constituting the variable resistive element) is represented by a line.

At the time of the forming process, as shown in FIG. 4A, a word line WL2 is applied with the voltage V_{form}, a bit line BL2 is applied with 0V, word lines WL1 and WL3 are applied with a voltage V_{passWL}, and bit lines BL1 and BL3 are applied with a voltage V_{passBL}. The resistive random access memory cell at the intersection position of the word line WL2 and the bit line BL2 becomes the selected cell, and other resistive random access memory cells become the non-selected cells. In the non-selected cell, as shown in FIG. 4B, there is almost no difference between voltages applied to the word line and the bit line, so that a carrier does not flow due to the influence of the Schottky barriers formed between the variable resistive element (the electrode 21/the variable resistive layer 22/the electrode 23) and the N-type and P-type semiconductor layers 10 and 30. On the other hand, in the selected cell, as shown in FIG. 4C, a forward voltage V_{form} is applied between the word line WL and the bit line BL. However, because the resistance of the variable resistive layer 22 is still high, the bias voltage is mainly applied to the variable resistive layer 22.

In the comparison example also, in the non-selected cell, as shown in FIG. 4D, because there is almost no difference between voltages applied to the word line WL2 and the bit line BL2, a carrier does not flow in the memory cell. On the other hand, in the selected cell, as shown in FIG. 4E, a forward voltage is applied between the word line WL2 and the bit line BL2, so that the current flows. Then, in the similar manner to the case of FIG. 4C, the bias voltage is mainly applied to the variable resistive layer 522.

### <After Completing Forming>

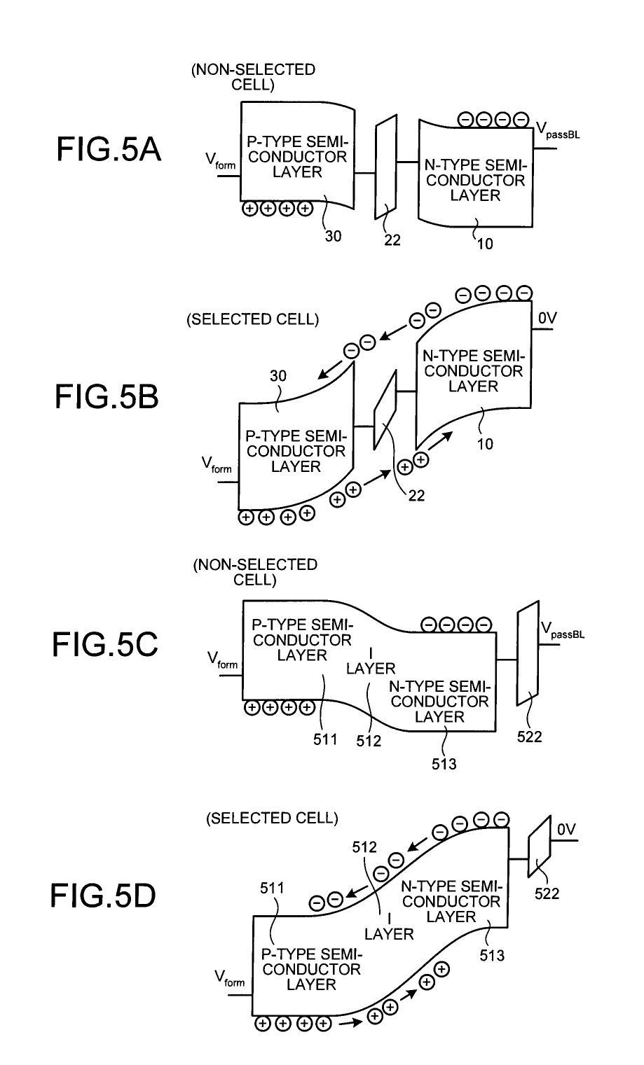

FIGS. 5A to 5D are diagrams each schematically illustrating the state of the resistive random access memory cell after completing the forming. FIG. 5A is a band diagram of the non-selected cell of the resistive random access memory cell according to the first embodiment, and FIG. 5B is an energy band diagram of the selected cell of the same. FIG. 5C is an energy band diagram of the non-selected cell of the resistive random access memory cell in the comparison example, and FIG. 5D is an energy band diagram of the selected cell of the same.

In the non-selected cell in the comparison example, as shown in FIG. 5C, because there is almost no difference between voltages applied to the word line and the bit line, the band state is the same as that shown in FIG. 4D. On the other hand, in the selected cell in the comparison example, as shown in FIG. 5D, after completing the forming process of the variable resistive layer 522, the band gap of the variable resistive layer 522 becomes small rapidly and the variable resistive layer 522 becomes the state of a conductor. Consequently, the electric field is concentrated at once in the I layer 512 as a high resistance layer of the PIN diode. Therefore, a rectifying layer may be broken.

In the non-selected cell of the resistive random access memory cell in the first embodiment, as shown in FIG. 5A, because there is almost no difference between voltages applied to the word line and the bit line, the energy band state is the same as that shown in FIG. 4B. In the selected cell, as shown in FIG. 5B, after completing the forming process of the variable resistive layer 22, the band gap of the variable resistive layer 22 shrinks rapidly and the variable resistive layer 22 becomes the state of a conductor. However, the structure of the resistive random access memory cell in the first embodiment is such that the variable resistive layer 22 is substantially sandwiched by two Schottky diodes and the I layer 512 having a high resistance as the comparison example does not present, so that the voltage is applied to the variable resistive layer 22. Consequently, the N-type semiconductor layer 10 and the P-type semiconductor layer 30 are not broken.

### <In Writing (Setting)>

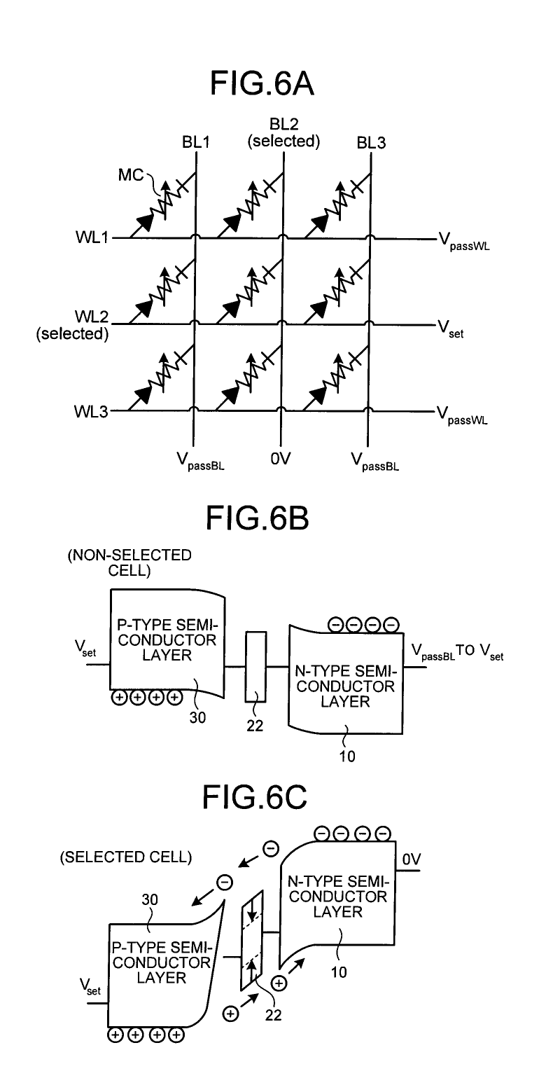

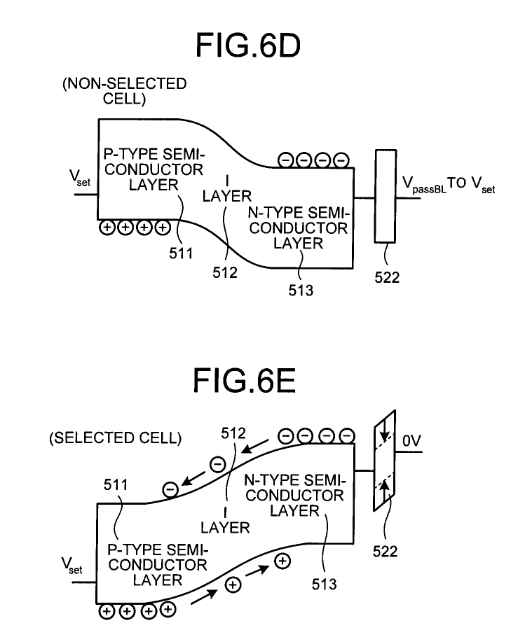

As described above, the writing process is a process of transitioning the variable resistive layer from a high resistance state to a low resistance state. FIGS. 6A to 6E are diagrams each schematically illustrating the state of the resistive random access memory cell at the time of the writing. FIG. 6A is a circuit diagram illustrating a voltage application state to the word lines and the bit lines in a selected/non-selected state, FIG. 6B is an energy band diagram of the non-selected cell in the early state of the writing of the resistive random access memory cell according to the first embodiment, and FIG. 6C is an energy band diagram of the selected cell of the same. FIG. 6D is an energy band diagram of the non-selected cell in the early state of the writing of the resistive random access memory cell in the comparison example, and FIG. 6E is an energy band diagram of the selected cell of the same.

As shown in FIG. 6A, the word line WL2 is applied with the write voltage Vₛₑₜ, the bit line BL2 is applied with 0V, the word lines WL1 and WL3 are applied with the voltage V_{passWL}, and the bit lines BL1 and BL3 are applied with the voltage V_{passBL}. The resistive random access memory cell at the intersection position of the word line WL2 and the bit line BL2 becomes the selected cell, and other resistive random access memory cells become the non-selected cells. The voltage Vₛₑₜ applied to the word line WL2 and the voltage V_{passBL} applied to the non-selected bit lines BL1 and BL3 are almost the same.

In the non-selected cell in the first embodiment and the comparison example, as shown in FIGS. 6B and 6D, because the voltages applied to the word line WL and the bit line BL are almost the same, a carrier does not flow.

On the other hand, in the selected cell in the first embodiment, as shown in FIG. 6C, the electric field is effectively applied to the variable resistive layer 22 sandwiched between the N-type semiconductor layer 10 and the P-type semiconductor layer 30 while the electric field is dispersed to the depletion layer (formed at the interface on the side of the variable resistive element 20) of the N-type semiconductor layer 10, the depletion layer (formed at the interface on the side of the variable resistive element 20) of the P-type semiconductor layer 30, and the Schottky barriers at the interfaces. The crystalline state of the variable resistive layer 22 is changed due to the electric field to be in the low resistance state, so that the band gap shrinks. Moreover, because the electric field is distributed, the leakage suppression due to the concentration of the electric field becomes easy.

On the contrary, in the selected cell in the comparison example, as shown in FIG. 6E, the electric field is applied to the variable resistive layer 522 in the high resistance state and the I layer 512 in a decentralized manner. The crystal state of the variable resistive layer 522 to which the electric field is applied is changed to the low resistance state, however, the electric field is also applied to the I layer 512 at the same time. Therefore, the electric field applied to the variable resistive layer 522 becomes small compared with the case of FIG. 6C. Consequently, it is difficult to effectively lower the resistance of the variable resistive layer 522 compared with the structure in the first embodiment.

### <In Erasing (Resetting)>

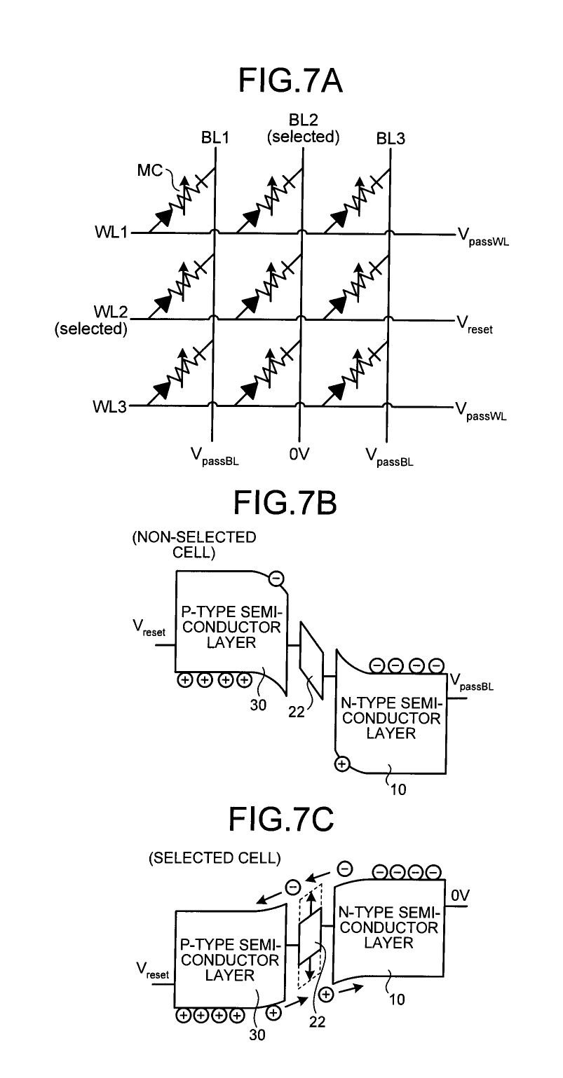

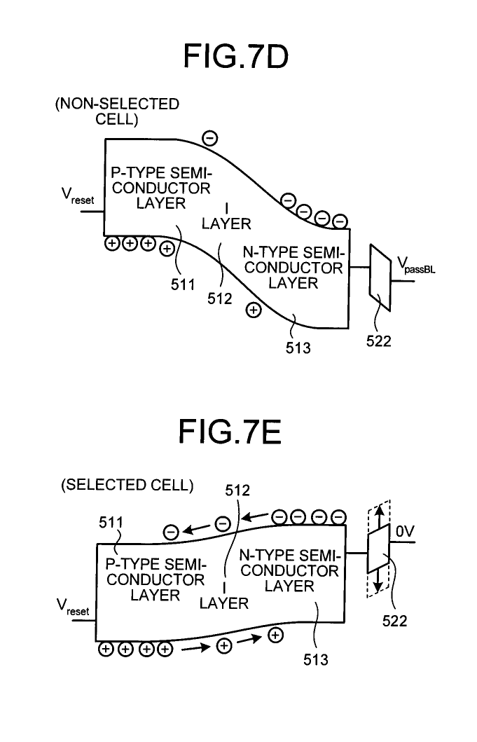

As described above, the erasing process is a process of transitioning the variable resistive layer from a low resistance state to a high resistance state. FIGS. 7A to 7E are diagrams each schematically illustrating the state of the resistive random access memory cell at the time of the erasing. FIG. 7A is a circuit diagram illustrating a voltage application state to the word lines and the bit lines in a selected/non-selected state, FIG. 7B is an energy band diagram of the non-selected cell in the early state of the erasing of the resistive random access memory cell according to the first embodiment, and FIG. 7C is an energy band diagram of the selected cell of the same. FIG. 7D is an energy band diagram of the non-selected cell in the early state of the erasing of the resistive random access memory cell in the comparison example, and FIG. 7E is an energy band diagram of the selected cell of the same.

As shown in FIG. 7A, the word line WL2 is applied with the erasing voltage Vᵣₑₛₑₜ, the bit line BL2 is applied with 0V, the word lines WL1 and WL3 are applied with the voltage V_{passWL}, and the bit lines BL1 and BL3 are applied with the voltage V_{passBL}. The resistive random access memory cell at the intersection position of the word line WL2 and the bit line BL2 becomes the selected cell, and other resistive random access memory cells become the non-selected cells. The non-selected cell in which the voltage Vᵣₑₛₑₜ is applied to the word line WL and the voltage V_{passBL} is applied to the bit line BL is in a reverse bias state. Moreover, the voltage Vᵣₑₛₑₜ applied to the word line WL of the selected cell is lower than the Vₛₑₜ applied to the word line WL of the selected cell at the time of the writing.

In the non-selected cell in the comparison example shown in FIG. 7D, because the resistance of the variable resistive layer 522 is in a low state in the early state, the electric field is concentrated only in the I layer 512 by performing the erasing process and thus the rectifier layer may be broken. On the contrary, in the non-selected cell in the first embodiment shown in FIG. 7B, the reserve voltage is applied same as FIG. 7D of the comparison example, however, because the voltage is dispersed to the depletion layers of the N-type and P-type semiconductor layers 10 and 30 and the Schottky barriers at the interfaces, possibility of causing breakdown of the depletion layers of the N-type and P-type semiconductor layers 10 and 30 is small.

On the other hand, in the selected cell in the first embodiment and the comparison example, as shown in FIGS. 7C and 7E, the forward voltage Vᵣₑₛₑₜ is mainly applied to the variable resistive layers 22 and 522. At this time, because the series resistance of the I layer 512 of the PIN diode is not interposed in the selected cell in the first embodiment compared with the case in the comparison example using the PIN diode, the electric field is effectively applied to the variable resistive layer 22. Then, the current flows in the variable resistive layer 22 and the crystal state of the variable resistive layer 22 changes due to heat generated by this current. Consequently, the variable resistive layer 22 becomes a high resistance state and the energy band gap expands.

As explained above, in the structure in the first embodiment, the depletion layer is generated at both of the N-type and P-type semiconductor layers 10 and 30 sandwiching the variable resistive layer 22, so that sufficient reverse breakdown voltage can be ensured in the similar manner to the PIN diode. Moreover, because the I layer having a high resistance does not present, sufficient forward current can be ensured compared with the PIN diode. Furthermore, since the Schottky junction is formed on the variable resistive layer 22 sides of the N-type and P-type semiconductor layers 10 and 30, the breakdown voltage of the Schottky junctions can be utilized in addition to the breakdown voltage of the depletion layers. Thus, the reverse breakdown voltage can be ensured more easily. Moreover, because the I layer such as the PIN diode does not present and interdiffusion of impurities does not occur, so that the film thickness of the N-type and P-type semiconductor layers 10 and 30 can be reduced, enabling to reduce the film thickness of the stacked film constituting the memory cell. Specially, the structure in the first embodiment is useful for suppressing a step of the stacked memory.

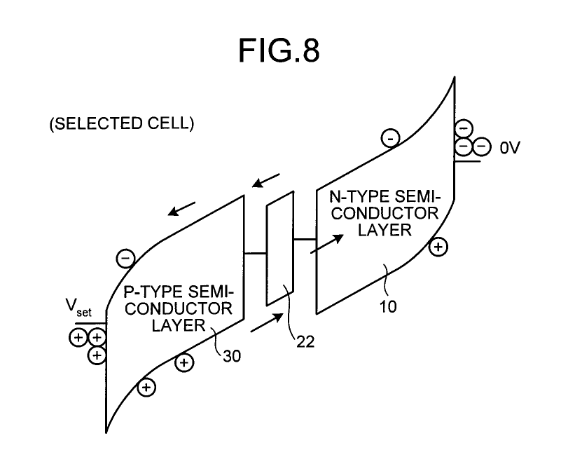

In the element structure in the first embodiment, explanation is given for the case where the electrode material is selected so that the ohmic contact is formed on the wire sides and the Schottky junction is formed on the variable resistive layer 22 sides of the N-type and P-type semiconductor layers 10 and 30. However, when the Schottky barrier is formed on the wire sides of the N-type and P-type semiconductor layers 10 and 30, the above operation cannot be performed on the formed memory cell. FIG. 8 is a diagram illustrating an example of an energy band diagram in the case where the Schottky barrier of each semiconductor layer is formed on the wire side. As shown in FIG. 8, when the Schottky barrier is formed on the wire sides of the N-type and P-type semiconductor layers 10 and 30, the Schottky barriers become obstacles and therefore sufficient forward current is difficult to ensure. Moreover, because the Schottky barrier does not present on the sides of the variable resistive layer 22, it becomes difficult to apply a voltage to the variable resistive layer 22. Therefore, in the nonvolatile memory device in the first embodiment, the Schottky barrier is not formed at the interface of the N-type or P-type semiconductor layer 10 or 30, or is formed on the sides of the variable resistive layer 22.

As described above, in the structure in the first embodiment, the forward current is easily ensured because the I layer 512 having a high resistance does not present compared with the PIN diode in the comparison example, enabling to realize favorable writing and erasing characteristics.

Next, the manufacturing method of the nonvolatile memory device having such a structure is explained. In this example, explanation is given for a case where a metal-insulator-metal (MIM) type variable resistive element of TiN/C/TiN is sandwiched by a P-type silicon layer and an N-type silicon layer and a W film is used as a stopper film at the time of a chemical mechanical polishing (CMP) process as an example.

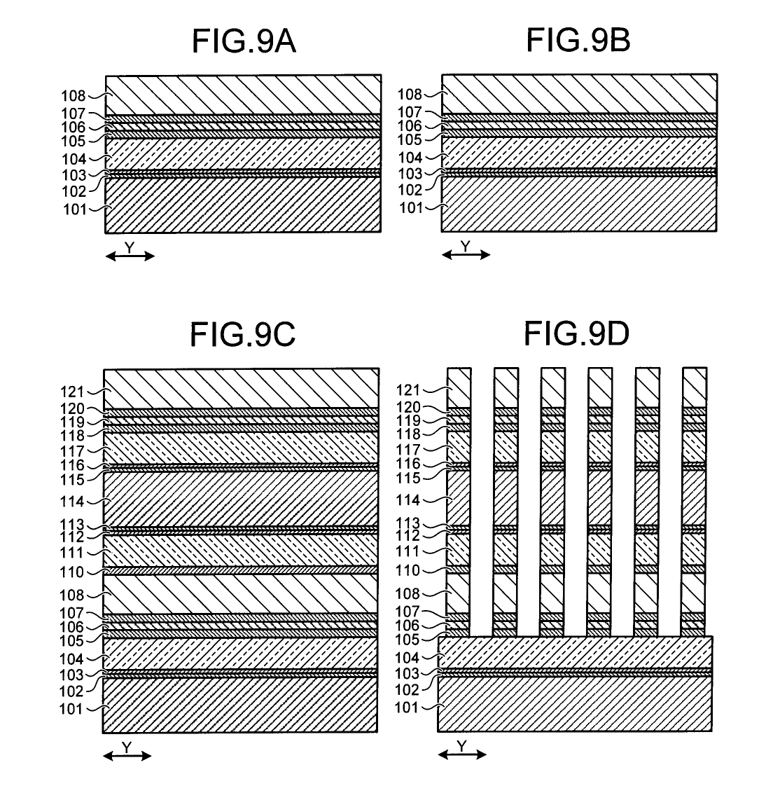

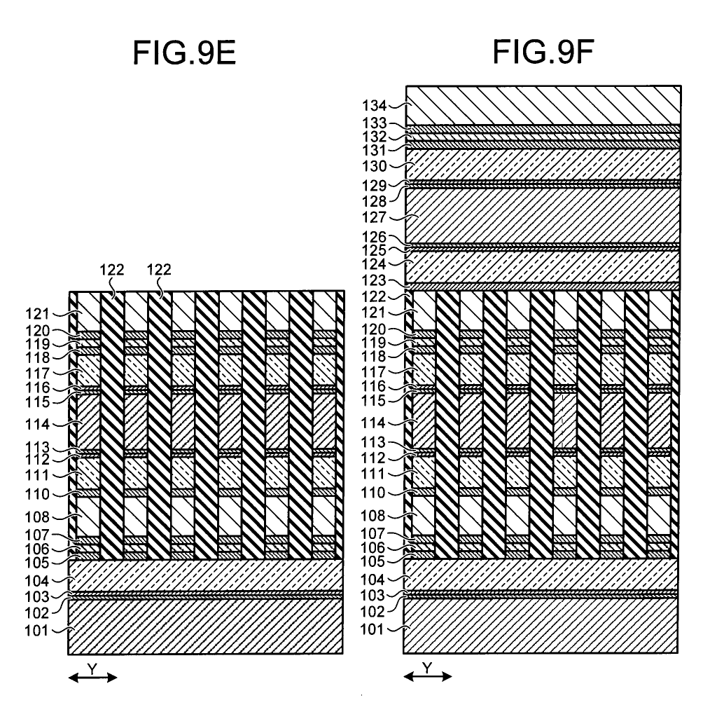

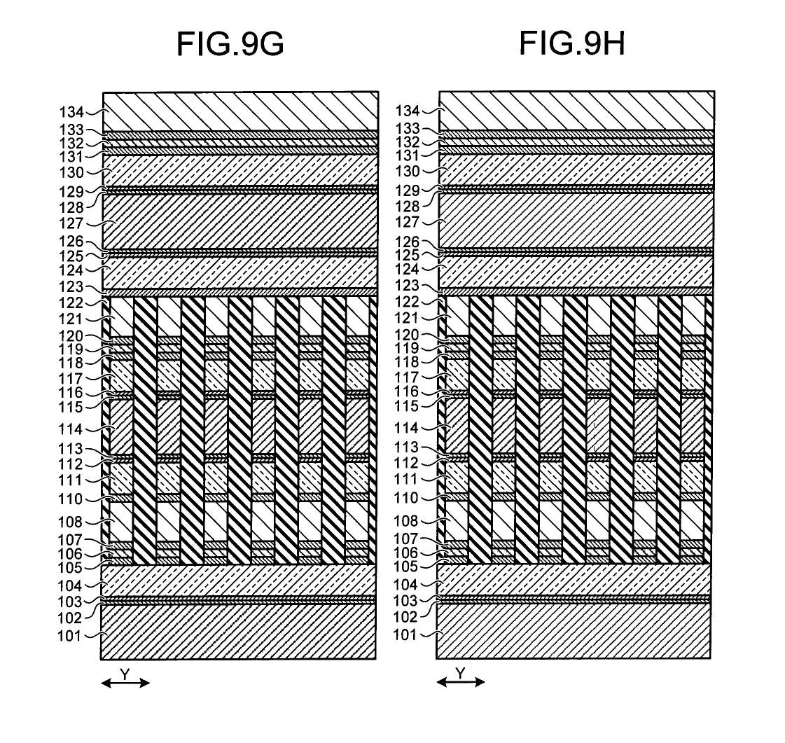

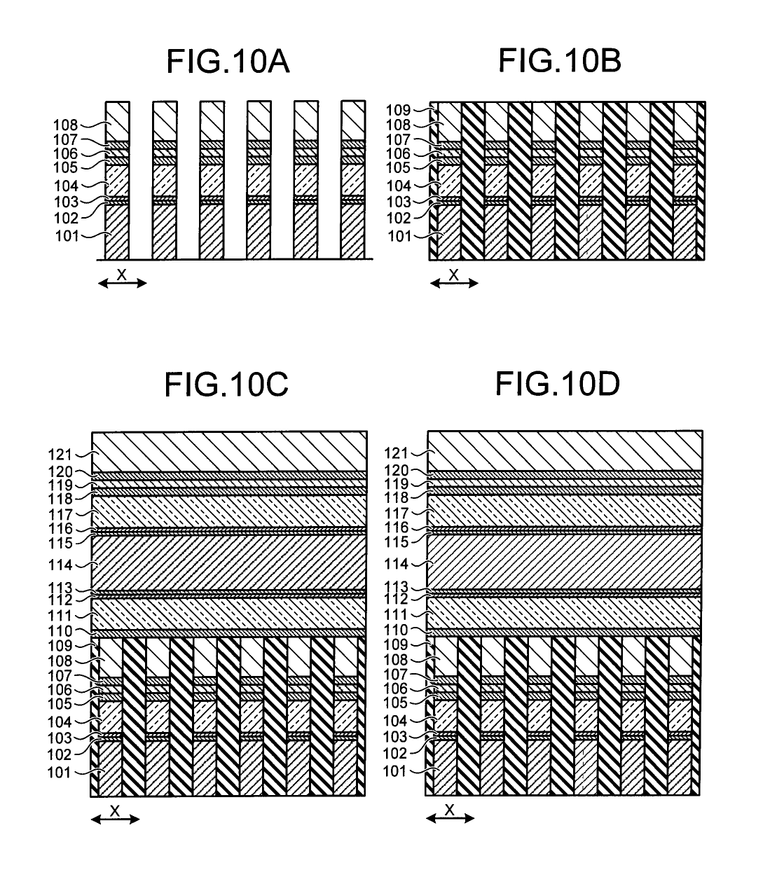

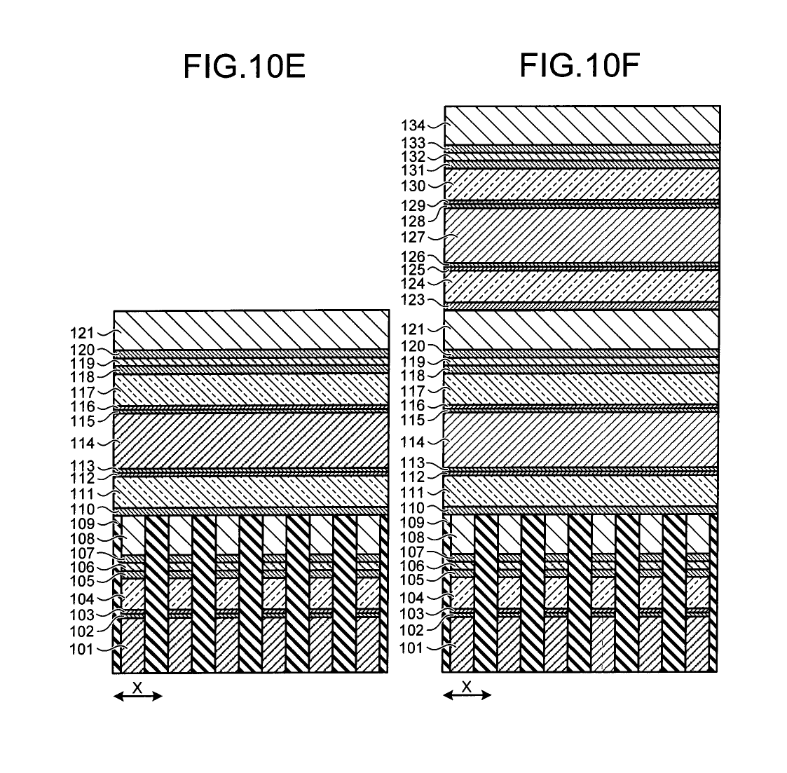

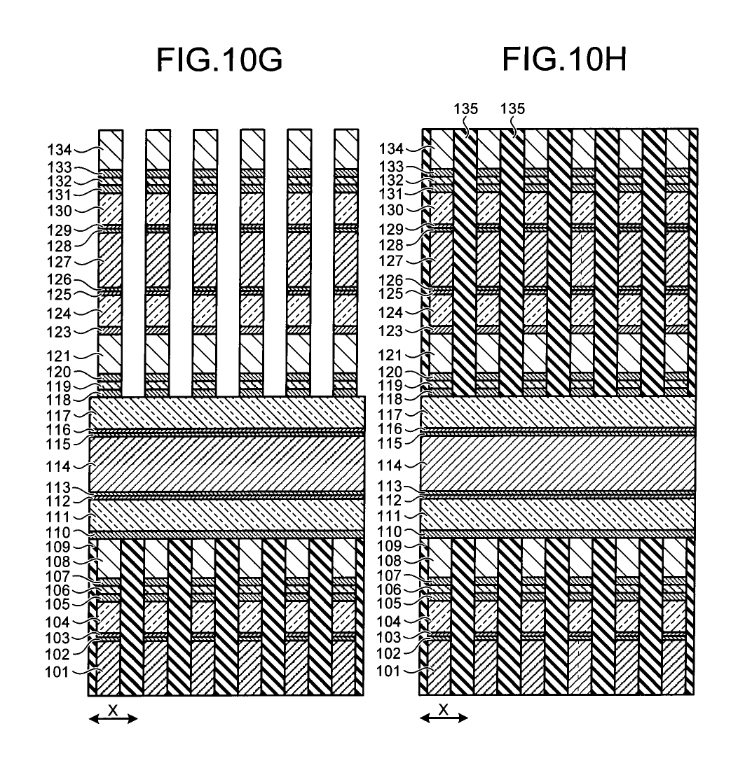

FIGS. 9A to 10H are cross-sectional views schematically illustrating an example of a procedure of the manufacturing method of the nonvolatile memory device according to the first embodiment. FIGS. 9A to 9H are cross-sectional views in a direction vertical to an extending direction (X direction) of the word line, and FIGS. 10A to 10H are cross-sectional views in a direction parallel to the extending direction of the word line. As described above, because the nonvolatile memory device in the first embodiment relates to the structure of the cell portion, the description of a forming process of a peripheral circuit and the like is omitted to avoid complication. Moreover, in the first embodiment, the laminated N-type semiconductor layer and P-type semiconductor layer of each memory cell are processed into a band shape along two wires of the bit line and the word line sandwiching the memory cell, respectively.

First, as shown in FIGS. 9A and 10A, a tungsten film 101 to be the bit line of the resistive random access memory, a titanium nitride film 102, and a titanium film 103 for forming titanium silicide are formed in order on a semiconductor substrate such as a silicon substrate (not shown) with the thickness of, for example, 70 nm, 5 nm, and 5 nm, respectively, by a film-forming method such as a sputtering method or a chemical vapor deposition (CVD) method. The titanium film 103 is provided to increase the adhesion between the titanium nitride film 102 and the N-type silicon film formed on the titanium film 103 and lower the contact resistance by forming titanium silicide. The tungsten film 101 as a base of the bit line does not always have to be the tungsten film 101 to be the bit line of the lowermost layer of the stacked memories.

Furthermore, an N-type semiconductor layer 104 composed of a P (phosphorus) doped polysilicon film is formed on the titanium film 103 with the thickness of 40 nm by a low pressure CVD (LPCVD) method. The N-type semiconductor layer 104 has a role of sandwiching the variable resistive element from the lower side. When the N-type semiconductor layer 104 is activated, the titanium film 103 on the lower side reacts with the N-type semiconductor layer 104 to form titanium silicide.

Next, a titanium nitride film 105 to be a lower electrode of the variable resistive layer is formed with the thickness of 10 nm by the sputtering method, a carbon (C) film 106 to be the variable resistive layer is formed with the thickness of 10 nm by a plasma enhanced CVD (PECVD) method, and thereafter, a titanium nitride film 107 to be an upper electrode of the variable resistive layer is formed with the thickness of 10 nm by the sputtering method. Moreover, a tungsten film 108 is formed with the thickness of 50 nm by the sputtering method. The tungsten film 108 functions as the stopper film at the subsequent CMP process of an inter-layer dielectric film.

Thereafter, a stacked film from the tungsten film 108 to the tungsten film 101 is collectively processed into a plate-like shape by the known lithography technique and reactive ion etching (RIE) technology (hereinafter, RIE method). Whereby, the tungsten film 101 becomes the bit line extending in the Y direction.

Next, as shown in FIGS. 9B and 10B, an inter-layer dielectric film 109 is formed over the entire surface of the semiconductor substrate by the film-forming method such as the PECVD method, the LPCVD method, or a coating method. Specifically, the inter-layer dielectric film 109 is formed to fill the space between the stacked films processed into the plate-like shape and to be thicker than the upper surface of the tungsten film 108. Thereafter, the upper surface of the inter-layer dielectric film 109 is planarized by the CMP method with the tungsten film 108 as a stopper.

Next, as shown in FIGS. 9C and 10C, a titanium nitride film 110 with the thickness of 5 nm is formed by the film-forming method such as the sputtering method or the CVD method on the tungsten film 108 and the inter-layer dielectric film 109. Moreover, a P-type semiconductor layer 111 composed of a B (boron) doped polysilicon film is formed on the titanium nitride film 110 with the thickness of 40 nm by the LPCVD method. The P-type semiconductor layer 111 has a role of sandwiching the variable resistive element (the titanium nitride film 105/the carbon film 106/the titanium nitride film 107) from the upper side.

Next, a titanium film 112 for forming titanium silicide, a titanium nitride film 113, and a tungsten film 114 to be the word line are formed in order on the P-type semiconductor layer 111 with the thickness of 5 nm, 5 nm, and 70 nm, respectively, by the sputtering method. When the P-type semiconductor layer 111 is activated, the titanium film 112 reacts with the P-type semiconductor layer 111 to form titanium silicide.

Furthermore, a titanium nitride film 115 and a titanium film 116 for forming titanium silicide are formed in order on the tungsten film 114 with the thickness of 5 nm by the sputtering method. Thereafter, a P-type semiconductor layer 117 composed of a B-doped polysilicon film is formed on the titanium film 116 with the thickness of 40 nm by the LPCVD method. The P-type semiconductor layer 117 has a role of sandwiching the variable resistive element from the lower side. When the P-type semiconductor layer 117 is activated, the titanium film 116 reacts with the P-type semiconductor layer 117 to form titanium silicide.

Next, a titanium nitride film 118 to be the lower electrode of the variable resistive layer is formed with the thickness of 10 nm by the sputtering method, a carbon film 119 to be the variable resistive layer is formed with the thickness of 10 nm by the PECVD method, and thereafter, a titanium nitride film 120 to be the upper electrode of the variable resistive layer is formed with the thickness of 10 nm by the sputtering method. Moreover, a tungsten film 121 is formed with the thickness of 50 nm by the sputtering method. The tungsten film 121 functions as the stopper film at the subsequent CMP process of the inter-layer dielectric film.

Next, as shown in FIGS. 9D and 10D, a stacked film from the tungsten film 121 to the titanium nitride film 105 is collectively processed into a plate-like shape by the known lithography technique and RIE method. At this time, the stacked film is processed into the plate-like shape to extend in the X direction that intersects with (in this example, orthogonal to) the Y direction. Whereby, the tungsten film 114 becomes the word line extending in the X direction.

With the above process, the N-type semiconductor layer 104 is cut only in the process same as the bit line (the tungsten film 101), so that the N-type semiconductor layer 104 becomes a shape extending in the Y direction. Moreover, the P-type semiconductor layer 111 is cut only in the process same as the word line (the tungsten film 114), so that the P-type semiconductor layer 111 becomes a shape extending in the X direction. Furthermore, a stacked film between the N-type semiconductor layer 104 and the P-type semiconductor layer 111 is processed into a columnar structure defined by the width of the bit line (the tungsten film 101) in the X direction and the width of the word line (the tungsten film 114) in the Y direction except for the titanium nitride film 110 just below the P-type semiconductor layer 111. Consequently, the memory cell of a first layer in which the variable resistive element having the MIM structure is sandwiched by the N-type and P-type semiconductor layers 104 and 111 is formed at the intersection position of the bit line (the tungsten film 101) and the word line (the tungsten film 114).

The N-type semiconductor layer 104 can be partially processed without stopping the processing after the titanium nitride film 105 is processed, however, the cross section area of the N-type semiconductor layer 104 in a direction parallel to the substrate surface of the N-type semiconductor layer 104 can be made large by processing the N-type semiconductor layer 104 in a plate-like shape, so that the series resistance of the N-type semiconductor layer 104 can be minimized. Consequently, the writing/erasing voltage can be efficiently applied to the variable resistive element.

Thereafter, as shown in FIGS. 9E and 10E, an inter-layer dielectric film 122 is formed to fill a space between the stacked films processed into the plate-like shape and to be thicker than the upper surface of the tungsten film 121 by the film-forming method such as the PECVD method, the LPCVD method, or the coating method. Thereafter, the upper surface of the inter-layer dielectric film 122 is planarized by the CMP method with the tungsten film 121 as a stopper.

Next, as shown in FIGS. 9F and 10F, a titanium nitride film 123 with the thickness of 5 nm is formed by the film-forming method such as the sputtering method or the CVD method on the tungsten film 121 and the inter-layer dielectric film 122. Moreover, an N-type semiconductor layer 124 composed of a P-doped polysilicon film is formed on the titanium nitride film 123 with the thickness of 40 nm by the LPCVD method. The N-type semiconductor layer 124 has a role of sandwiching the variable resistive element (the titanium nitride film 118/the carbon film 119/the titanium nitride film 120) from the upper side.

Next, a titanium film 125 for forming titanium silicide, a titanium nitride film 126, and a tungsten film 127 to be the bit line are formed in order on the N-type semiconductor layer 124 with the thickness of 5 nm, 5 nm, and 70 nm, respectively, by the sputtering method. When the N-type semiconductor layer 124 is activated, the titanium film 125 reacts with the N-type semiconductor layer 124 to form titanium silicide film.

Furthermore, a titanium nitride film 128 and a titanium film 129 for forming titanium silicide are formed in order on the tungsten film 127 with the thickness of 5 nm by the sputtering method. Thereafter, an N-type semiconductor layer 130 composed of a P-doped polysilicon film is formed on the titanium film 129 with the thickness of 40 nm by the LPCVD method. The N-type semiconductor layer 130 has a role of sandwiching the variable resistive element to be formed next from the lower side. When the N-type semiconductor layer 130 is activated, the titanium film 129 reacts with the N-type semiconductor layer 130 to form titanium silicide film.

Next, a titanium nitride film 131 to be the lower electrode of the variable resistive layer is formed with the thickness of 10 nm by the sputtering method, a carbon film 132 to be the variable resistive layer is formed with the thickness of 10 nm by the PECVD method, and thereafter, a titanium nitride film 133 to be the upper electrode of the variable resistive layer is formed with the thickness of 10 nm by the sputtering method. Moreover, a tungsten film 134 is formed with the thickness of 50 nm by the sputtering method. The tungsten film 134 functions as a stopper at the subsequent CMP process of the inter-layer dielectric film.

Next, as shown in FIGS. 9G and 10G, a stacked film from the tungsten film 134 to the titanium nitride film 118 is collectively processed into a plate-like shape by the known lithography technique and RIE method. At this time, the stacked film is processed into the plate-like shape to extend in the Y direction. Whereby, the tungsten film 127 becomes the bit line extending in the Y direction.

With the above process, the N-type semiconductor layer 124 is cut only in the process same as the bit line (the tungsten film 127), so that the N-type semiconductor layer 124 becomes a shape extending in the Y direction. Moreover, the P-type semiconductor layer 117 is cut only in the process same as the word line (the tungsten film 114), so that the P-type semiconductor layer 117 becomes a shape extending in the X direction. Furthermore, a laminated film between the P-type semiconductor layer 117 and the N-type semiconductor layer 124 is processed into a columnar structure defined by the width of the bit line (the tungsten film 127) in the X direction and the width of the word line (the tungsten film 114) in the Y direction except for the titanium nitride film 123 just below the N-type semiconductor layer 124. Consequently, the memory cell of a second layer in which the variable resistive element having the MIM structure is sandwiched by the N-type and P-type semiconductor layers 124 and 117 is formed at the intersection position of the bit line (the tungsten film 127) and the word line (the tungsten film 114).

Thereafter, as shown in FIGS. 9H and 10H, an inter-layer dielectric film 135 is formed to fill a space between the stacked films processed into the plate-like shape and to be thicker than the upper surface of the tungsten film 134 by the film-forming method such as the PECVD method, the LPCVD method, or the coating method. Thereafter, the upper surface of the inter-layer dielectric film 135 is planarized by the CMP method with the tungsten film 134 as a stopper.

Thereafter, the process similar to that from FIGS. 9C and 10C to FIGS. 9H and 10H is repeated a plurality of times, whereby the resistive random access memory cells can be laminated in multiple layers. When a memory layer of an uppermost layer is formed, for example, in FIGS. 9F and 10F, a laminated film from the tungsten film 127 to the titanium nitride film 118 is collectively processed into a plate-like shape extending in the Y direction by the lithography technique and the RIE method after forming the tungsten film 127 to be the bit line. Then, the inter-layer dielectric film 135 is filled between the processed stacked films and the CMP process is performed with the tungsten film 127 as the stopper film, and the process ends. With the above process, the nonvolatile memory device having a structure in which the memory layers, in each of which the variable resistive element is sandwiched by the semiconductor layers having different polarities, are three-dimensionally laminated at each intersection position of the first and second wires can be obtained.

In the above explanation, an example is given for the case where a tungsten film is used as the stopper film in the CMP process, however, other conductive metals, a polysilicon used in the second embodiment, or the like can also be used.

Moreover, in the above explanation, the carbon film is used as the variable resistive material, however, any material of which resistance state changes by a voltage applied to both sides can be used. As such a material, for example, at least one material selected from the group consisting of NbOₓ, Ti-doped NiOₓ, Cr-doped SrTiO₃₋ₓ, PrₓCa_{y}MnO_{z}, ZrOₓ, NiOₓ, ZnOₓ, TiOₓ, TiOₓN_{y}, CuOₓ, GdOₓ, CuTeₓ, HfOₓ, ZnMnₓO_{y}, and ZnFeₓO_{y} can be used. Furthermore, GST (GeSbₓTe_{y}), N-doped GST, O-doped GST, GeSb, InGeₓTe_{y}, and the like of the chalcogenide system of which resistance state changes due to the Joule heat generated by the voltage applied to both sides can also be used.

Moreover, in the above explanation, the titanium nitride is used as the MIM electrode material, however, any material that does not detract from the variable resistance characteristics thereof by reacting with the variable resistive material or a heater material can be used. As such a material, for example, tungsten nitride, titanium aluminum nitride, tantalum nitride, titanium nitride silicide, tantalum carbide, titanium silicide, tungsten silicide, cobalt silicide, nickel silicide, tantalum nitride silicide, nickel platinum silicide, platinum, ruthenium, platinum rhodium, and iridium can be used.

According to the first embodiment, the structure is such that the variable resistive element is sandwiched between the N-type semiconductor layer and the P-type semiconductor layer, so that the depletion layer can be formed at the interfaces on the sides of the variable resistive element of the N-type semiconductor layer and the P-type semiconductor layer. Therefore, the voltage that is applied to the I layer in the case of a conventional structure in which the PIN diode and the variable resistive layer are connected in series can be effectively applied to the variable resistive layer. Moreover, the junction on the variable resistive layer sides of the N-type semiconductor layer and the P-type semiconductor layer is the Schottky junction, so that the breakdown voltage by the Schottky junction can be further added to the breakdown voltage by the depletion layer formed at each of the N-type semiconductor layer and the P-type semiconductor layer. Therefore, the reverse breakdown voltage can be easily ensured. Furthermore, because the I layer with high resistance does not present, favorable forward current can be ensured compared with the PIN diode.

Moreover, because the I layer is omitted compared with the conventional structure in which the PIN diode and the variable resistive layer are arranged in series, the height of the memory cell can be suppressed. Whereby, the increase in the aspect ratio in processing a diode can be suppressed even when the diode is shrunk, so that occurrence of a pattern collapse or a pattern bending can be suppressed. Consequently, the integration can be performed easily compared with the conventional structure. Furthermore, because the I layer such as the PIN diode does not present and thus interdiffusion of impurities does not occur, the present embodiment has an advantage in that restriction on the thermal process is low.

Furthermore, the N-type semiconductor layer and the P-type semiconductor layer are processed at the same time with the word line or the bit line and are formed to have a plate-like shape same as the word line or the bit line to make the cross section areas of the N-type semiconductor layer and the P-type semiconductor layer large, so that the series resistance in the forward direction can be suppressed sufficiently even when the density of impurities in these semiconductor layers is suppressed. Typically, for lowering the resistance in the forward direction, the semiconductor layer needs to be doped with impurities at high density. However, this makes it difficult to generate the depletion layer, so that the reverse breakdown voltage is difficult to ensure. However, as described above, in the first embodiment, the depletion layer of the semiconductor layer can be extended by lowering the density of impurities in the semiconductor layer, enabling to easily ensure the reverse breakdown voltage.

Moreover, because the N-type semiconductor layer, the P-type semiconductor layer, and the variable resistive layer are processed at the same time with the word line or the bit line, the time for etching can be reduced compared with the case of processing the N-type semiconductor layer, the P-type semiconductor layer, and the variable resistive layer into a columnar structure on the bit line or the word line. Furthermore, the memory cell structure can be formed by performing the process twice for each memory cell layer.

Furthermore, as shown in FIGS. 9H and 10H, when memory cells are stacked in multiple layers, the word line (the tungsten film 114) of the memory cell of the first layer also becomes the word line (the tungsten film 114) of the memory cell of the second layer, and the bit line (the tungsten film 127) of the memory cell of the second layer also becomes the bit line (the tungsten film 127) of the memory cell of the third layer. In this manner, the word line or the bit line of the memory cells that are adjacent to each other in an up and down direction can be shared, so that the height of the nonvolatile device formed by stacking the memory cells can be suppressed.

### Second Embodiment

In the first embodiment, explanation is given for the case where the tungsten film is used as the stopper film at the CMP process of the inter-layer dielectric film, however, in the second embodiment, the P-type semiconductor layer or the N-type semiconductor layer is used as the stopper film at the CMP process of the inter-layer dielectric film and the manufacturing method of the nonvolatile memory device in the case of sandwiching the MIM-type variable resistive element of WN/NiOₓ/WN by the P-type semiconductor layer and the N-type semiconductor layer is explained.

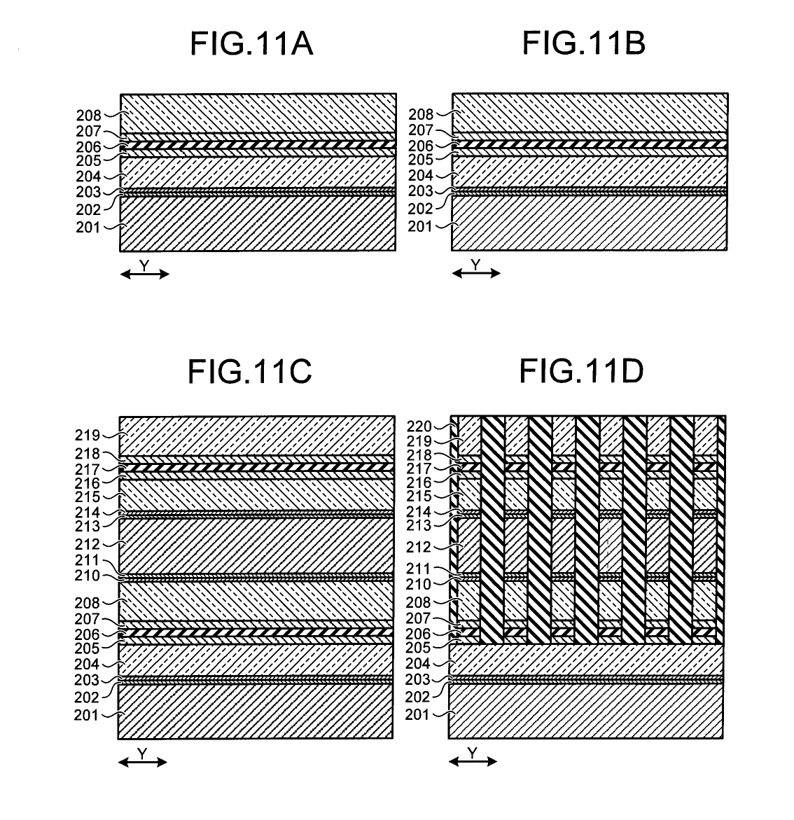

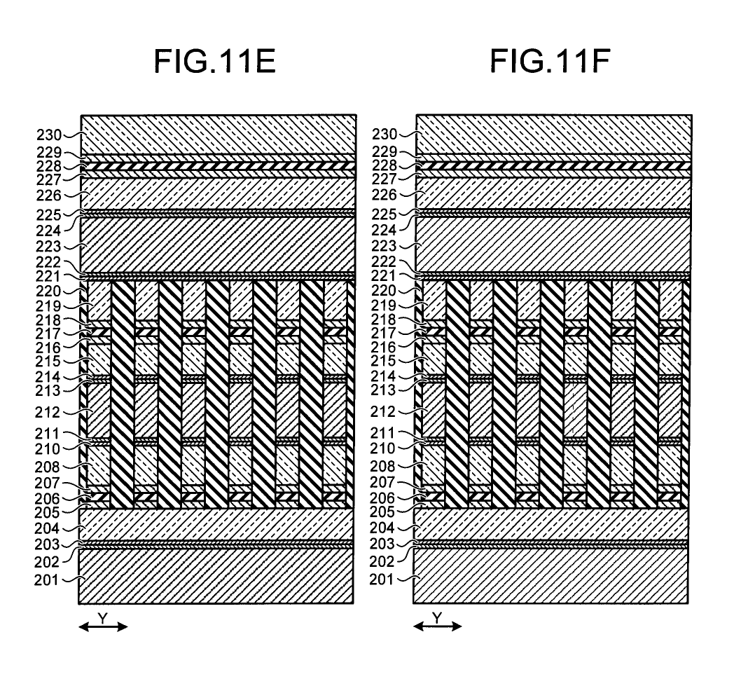

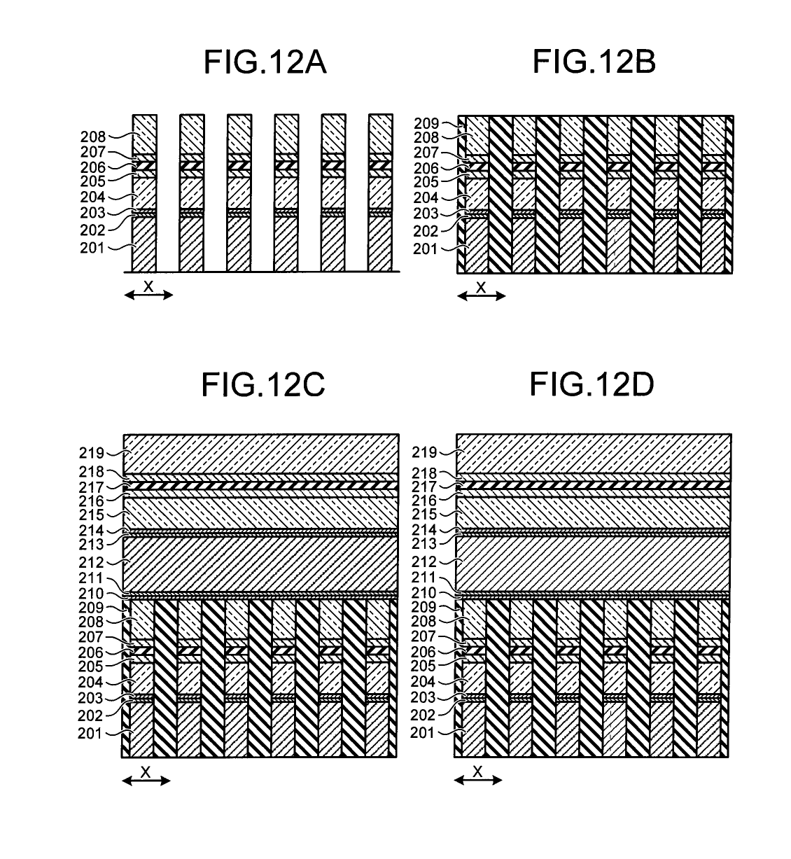

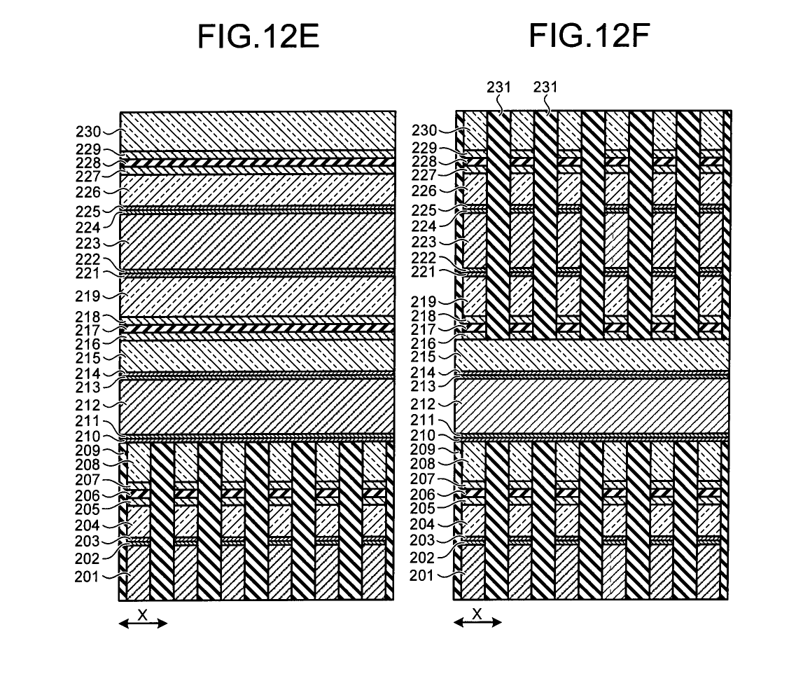

FIGS. 11A to 12F are cross sectional views schematically illustrating an example of a procedure of the manufacturing method of the nonvolatile memory device according to the second embodiment. FIGS. 11A to 11F are cross-sectional views in the direction vertical to the extending direction (X direction) of the word line and FIGS. 12A to 12F are cross-sectional views in the direction parallel to the extending direction of the word line. As described above, because the nonvolatile memory device in the present embodiment relates to the structure of the cell portion, the description of formation of a peripheral circuit and the like is omitted to avoid complication.

First, as shown in FIGS. 11A and 12A, a tungsten film 201 to be the bit line of the resistive random access memory, a titanium nitride film 202, and a titanium film 203 for forming titanium silicide are formed in order on a semiconductor substrate such as a silicon substrate (not shown) with the thickness of, for example, 70 nm, 5 nm, and 5 nm, respectively, by the film-forming method such as the sputtering method or the CVD method. In the similar manner to the first embodiment, the tungsten film 201 as a base of the bit line does not always have to be the bit line of the lowermost layer of the stacked memories.

Furthermore, an N-type semiconductor layer 204 composed of a P-doped polysilicon film is formed on the titanium film 203 with the thickness of 50 nm by the LPCVD method. The N-type semiconductor layer 204 has a role of sandwiching the variable resistive element from the lower side. When the N-type semiconductor layer 204 is activated, the titanium film 203 on the lower side reacts with the N-type semiconductor layer 204 to form titanium silicide.

Next, a tungsten nitride (WN) film 205 to be a barrier metal film and the lower electrode of the variable resistive layer is formed with the thickness of 10 nm by the sputtering method, an NiOₓ film 206 to be the variable resistive layer is formed with the thickness of 10 nm, and thereafter, a tungsten nitride film 207 to be the upper electrode of the variable resistive layer and the barrier metal film is formed with the thickness of 10 nm. Moreover, a P-type semiconductor layer 208 composed of a B-doped polysilicon film is formed on the tungsten nitride film 207 with the thickness of 50 nm by the sputtering method. The P-type semiconductor layer 208 sandwiches the variable resistive element from the upper side and functions as the stopper film at the subsequent CMP process of the inter-layer dielectric film.

Thereafter, a stacked film from the P-type semiconductor layer 208 to the tungsten film 201 is collectively processed into a plate-like shape by the known lithography technique and RIE method. Whereby, the tungsten film 201 becomes the bit line extending in the Y direction.

Next, as shown in FIGS. 11B and 12B, an inter-layer dielectric film 209 is formed over the entire surface of the semiconductor substrate by the film-forming method such as the PECVD method, the LPCVD method, or the coating method. Specifically, the inter-layer dielectric film 209 is formed to fill the space between the stacked films processed into the plate-like shape and to be thicker than the upper surface of the P-type semiconductor layer 208. Thereafter, the upper surface of the inter-layer dielectric film 209 is planarized by the CMP method with the P-type semiconductor layer 208 as a stopper.

Next, as shown in FIGS. 11C and 12C, a titanium film 210 for forming titanium silicide, a titanium nitride film 211 as the barrier metal film, a tungsten film 212 to be the word line, a titanium nitride film 213 as the barrier metal film, a titanium film 214 for forming titanium silicide, a P-type semiconductor layer 215 composed of a B-doped polysilicon film are formed in order on the P-type semiconductor layer 208 and the inter-layer dielectric film 209 with the thickness of 5 nm, 5 nm, 70 nm, 5 nm, 5 nm, and 50 nm, respectively, by the sputtering method. The P-type semiconductor layer 215 has a role of sandwiching the variable resistive element to be formed later from the lower side. When the P-type semiconductor layers 208 and 215 are activated, the titanium films 210 and 214 react with the P-type semiconductor layers 208 and 215, respectively, to form titanium silicide.

Furthermore, a tungsten nitride film 216 as the barrier metal film and the lower electrode film, an NiOₓ film 217 to be the variable resistive layer, and a tungsten nitride film 218 as the upper electrode and the barrier metal film are formed with the thickness of 10 nm by the sputtering method. Moreover, an N-type semiconductor layer 219 composed of a P-doped polysilicon film is formed on the tungsten nitride film 218 with the thickness of 50 nm by the sputtering method. The N-type semiconductor layer 219 sandwiches the variable resistive element from the upper side and functions as the stopper film in the subsequent CMP process.

Next, as shown in FIGS. 11D and 12D, a stacked film from the N-type semiconductor layer 219 to the tungsten nitride film 205 is collectively processed into a plate-like shape by the known lithography technique and RIE method. At this time, the stacked film is processed into the plate-like shape to extend in the X direction that intersects with (in this example, orthogonal to) the Y direction. Whereby, the tungsten film 212 becomes the word line extending in the X direction.

Thereafter, an inter-layer dielectric film 220 is formed on the entire surface of the semiconductor substrate by the film-forming method such as the PECVD method, the LPCVD method, or the coating method. Specifically, the inter-layer dielectric film 220 is formed to fill the space between the stacked films processed into the plate-like shape and to be thicker than the upper surface of the N-type semiconductor layer 219. Thereafter, the upper surface of the inter-layer dielectric film 220 is planarized by the CMP method with the N-type semiconductor layer 219 as a stopper.

With the above process, the N-type semiconductor layer 204 is cut only in the process same as the bit line (the tungsten film 201), so that the N-type semiconductor layer 204 becomes a shape extending in the Y direction. Moreover, the P-type semiconductor layer 208 is cut in the processes same as the bit line (the tungsten film 201) and the word line (the tungsten film 212), so that the P-type semiconductor layer 208 becomes not a plate-like shape but a columnar shape. Furthermore, a stacked film between the N-type semiconductor layer 204 and the titanium film 210 (word line (the tungsten film 212)) is processed into a columnar structure defined by the width of the bit line (the tungsten film 201) in the X direction and the width of the word line (the tungsten film 212) in the Y direction. Consequently, the memory cell of a first layer in which the variable resistive element having the MIM structure is sandwiched by the N-type and P-type semiconductor layers 204 and 208 is formed at the intersection position of the bit line (the tungsten film 201) and the word line (the tungsten film 212).

Next, as shown in FIGS. 11E and 12E, a titanium film 221 for forming titanium silicide, a titanium nitride film 222 as the barrier metal film, a tungsten film 223 to be the bit line, a titanium nitride film 224 to be the barrier metal film, a titanium film 225 for forming titanium silicide, and an N-type semiconductor layer 226 that sandwiches the variable resistive layer from the lower side and is composed of a P-doped polysilicon film are formed in order on the N-type semiconductor layer 219 and the inter-layer dielectric film 220 with the thickness of 5 nm, 5 nm, 70 nm, 5 nm, 5 nm, and 50 nm, respectively, by the sputtering method. When the N-type semiconductor layers 219 and 226 are activated, the titanium films 221 and 225 react with the N-type semiconductor layers 219 and 226, respectively, to form titanium silicide.

Thereafter, a tungsten nitride film 227 as the barrier metal film and the lower electrode film, an NiOₓ film 228 as the variable resistive layer, a tungsten nitride film 229 as the upper electrode and the barrier metal film are formed with the thickness of 10 nm by the sputtering method. Moreover, a P-type semiconductor layer 230 composed of a B-doped polysilicon film is formed with the thickness of 50 nm by the sputtering method. The P-type semiconductor layer 230 has a role of sandwiching the variable resistive element from the upper side and as the stopper film in the subsequent CMP process.

Next, as shown in FIGS. 11F and 12F, a stacked film from the P-type semiconductor layer 230 to the tungsten nitride film 216 is collectively processed into a plate-like shape extending in the Y direction by the known lithography technique and RIE method. Whereby, the tungsten film 223 becomes the bit line extending in the Y direction.

Next, an inter-layer dielectric film 231 is formed to fill a space between the stacked films processed into the plate-like shape and to be thicker than the upper surface of the P-type semiconductor layer 230 by the film-forming method such as the PECVD method, the LPCVD method, or the coating method. Thereafter, the upper surface of the inter-layer dielectric film 231 is planarized by the CMP method with the P-type semiconductor layer 230 as a stopper.

With the above process, the P-type semiconductor layer 215 is cut only in the process same as the word line (the tungsten film 212), so that the P-type semiconductor layer 215 becomes a shape extending in the X direction. Moreover, the N-type semiconductor layer 219 is cut in the processes same as the word line (the tungsten film 212) and the bit line (the tungsten film 223), so that the N-type semiconductor layer 219 becomes not a plate-like shape but a columnar shape. Furthermore, a stacked film between the P-type semiconductor layer 215 and the titanium film 221 (bit line (the tungsten film 223)) is processed into a columnar structure defined by the width of the word line (the tungsten film 212) in the Y direction and the width of the bit line (the tungsten film 223) in the X direction. Consequently, the memory cell of a second layer in which the variable resistive element having the MIM structure is sandwiched by the P-type and N-type semiconductor layers 215 and 219 is formed at the intersection position of the word line (the tungsten film 212) and the bit line (the tungsten film 223).

Thereafter, the process similar to that from FIGS. 11C and 12C to FIGS. 11F and 12F is repeated a plurality of times, whereby the resistive random access memory cells can be stacked in multiple layers. When a memory layer of an uppermost layer is formed, for example, in FIGS. 11E and 12E, a stacked film from the tungsten film 223 to the tungsten nitride film 216 is collectively processed into a plate-like shape extending in the Y direction by the lithography technique and the RIE method after forming the tungsten film 223 to be the bit line. Then, the inter-layer dielectric film 231 is filled between the processed stacked films and the CMP process is performed with the tungsten film 223 as the stopper film, and the process ends. With the above process, the nonvolatile memory device having a structure in which the memory layers, in each of which the variable resistive element is sandwiched by the semiconductor layers having different polarities, are three-dimensionally stacked at each intersection position of the first and second wires can be obtained.

In the above explanation, the NiOₓ film is used as the variable resistive film, however, any material of which resistance state changes by a voltage applied to both sides can be used. As such a material, for example, at least one material selected from the group consisting of C, NbOₓ, Cr-doped SrTiO₃₋ₓ, PrₓCa_{y}MnO_{z}, ZrOₓ, Ti-doped NiOₓ, ZnOₓ, TiOₓ, TiOₓN_{y}, CuOₓ, GdOₓ, CuTeₓ, HfOₓ, ZnMnₓO_{y}, and ZnFeₓO_{y} can be used. Furthermore, GST, N-doped GST, O-doped GST, GeSb, InGeₓTe_{y}, and the like of the chalcogenide system of which resistance state changes due to the Joule heat generated by the voltage applied to both sides can also be used.

Moreover, in the above explanation, the tungsten nitride is used as the MIM electrode material, however, any material that does not detract from the variable resistance characteristics thereof by reacting with the variable resistive material or a heater material can be used. As such a material, for example, titanium nitride, titanium aluminum nitride, tantalum nitride, titanium nitride silicide, tantalum carbide, titanium silicide, tungsten silicide, cobalt silicide, nickel silicide, tantalum nitride silicide, nickel platinum silicide, platinum, ruthenium, platinum rhodium, and iridium can be used.

According to the second embodiment, the P-type or N-type semiconductor layer that sandwiches the variable resistive layer functions as the stopper film without separately providing the stopper film composed of a tungsten film or the like as in the first embodiment at the CMP process of the inter-layer dielectric film. Therefore, the height can be reduced by the thickness of the separately provided stopper film compared with the first embodiment. Thus, the effect of further making the processing of the stacked layer structure easy can be obtained in addition to the effects in the first embodiment.

### Third Embodiment

In the first and second embodiments, the variable resistive layer is processed into a columnar structure defined by the width of the bit line and the width of the word line. In this case, the variable resistive layer can be a semiconductor or an insulator. In the third embodiment, the manufacturing method of the nonvolatile memory device in the case where the variable resistive layer before the forming process is an insulator is explained. Moreover, in the third embodiment, the structure is such that a hafnia film as the variable resistive layer is directly sandwiched by the P-type semiconductor layer and the N-type semiconductor layer, and the P-type semiconductor layer or the N-type semiconductor layer is used as a CMP stopper film.

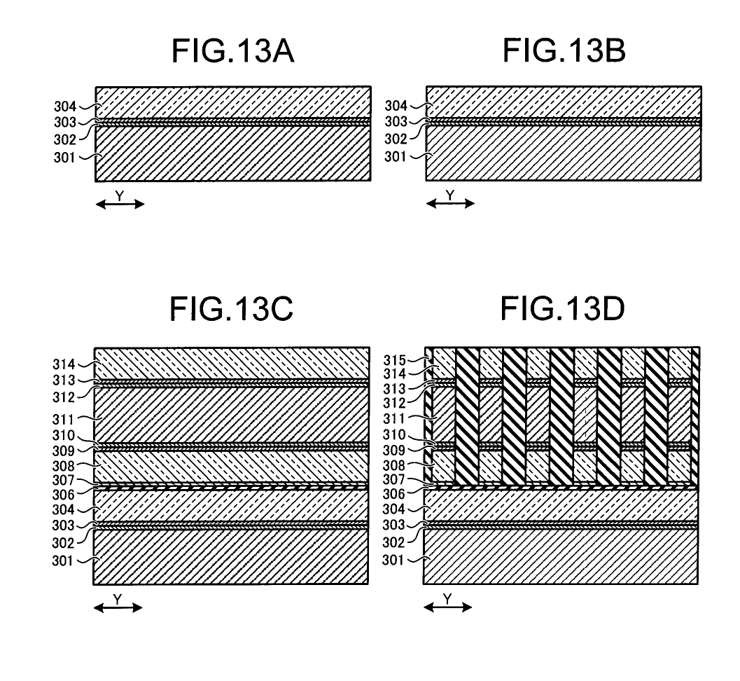

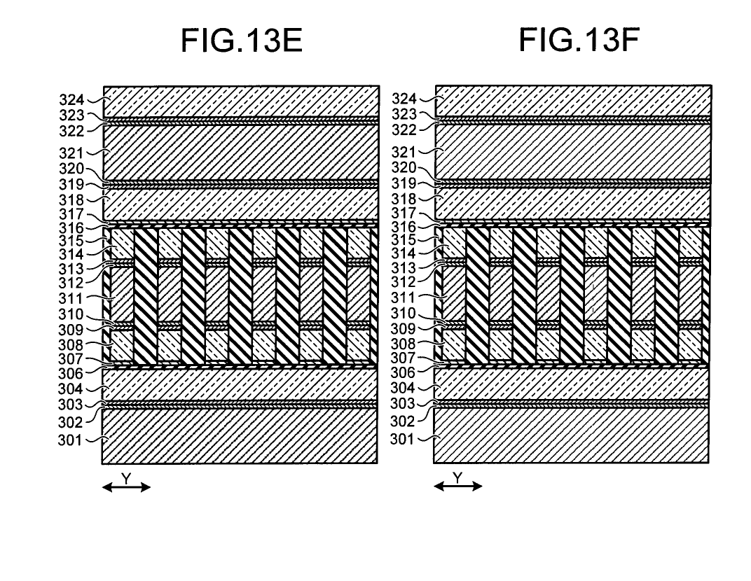

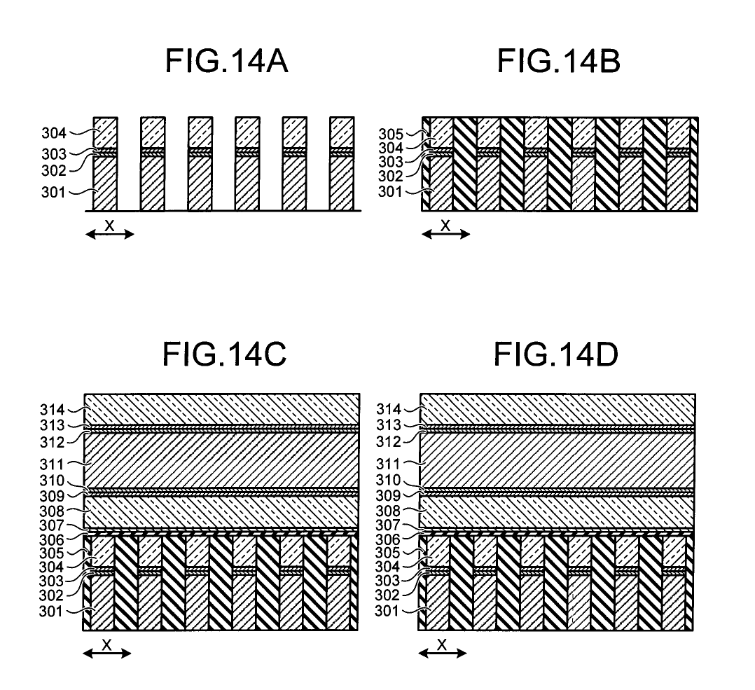

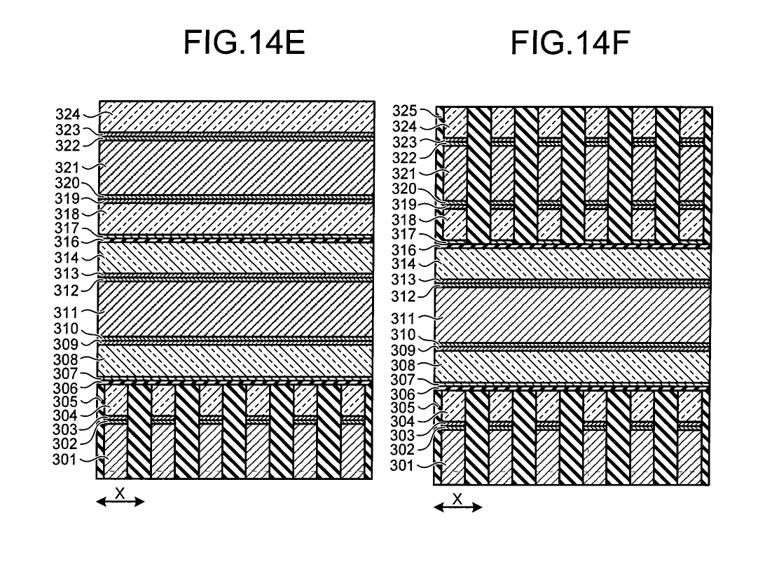

FIGS. 13A to 14F are cross sectional views schematically illustrating an example of a procedure of the manufacturing method of the nonvolatile memory device according to the third embodiment. FIGS. 13A to 13F are cross-sectional views in the direction vertical to the extending direction (X direction) of the word line and FIGS. 14A to 14F are cross-sectional views in the direction parallel to the extending direction of the word line. As described above, because the nonvolatile memory device in the present embodiment relates to the structure of the cell portion, the description of formation of a peripheral circuit and the like is omitted to avoid complication.

First, as shown in FIGS. 13A and 14A, a tungsten film 301 to be the bit line of the resistive random access memory, a titanium nitride film 302, and a titanium film 303 for forming titanium silicide are formed in order on a semiconductor substrate such as a silicon substrate (not shown) with the thickness of, for example, 70 nm, 5 nm, and 5 nm, respectively, by the film-forming method such as the sputtering method or the CVD method. In the similar manner to the first embodiment, the tungsten film 301 as a base of the bit line does not always have to be the bit line on the lowermost layer of the laminated memories.

Furthermore, an N-type semiconductor layer 304 composed of a P-doped polysilicon film is formed on the titanium film 303 with the thickness of 50 nm by the LPCVD method. The N-type semiconductor layer 304 has a role of sandwiching the variable resistive element from the lower side and as the stopper film at the CMP process of the inter-layer dielectric film to be formed. When the N-type semiconductor layer 304 is activated, the titanium film 303 reacts with the N-type semiconductor layer 304 to form titanium silicide.

Thereafter, a stacked film from the N-type semiconductor layer 304 to the tungsten film 301 is collectively processed into a plate-like shape by the known lithography technique and RIE method. Whereby, the tungsten film 301 becomes the bit line extending in the Y direction.

Next, as shown in FIGS. 13B and 14B, an inter-layer dielectric film 305 is formed over the entire surface of the semiconductor substrate by the film-forming method such as the PECVD method, the LPCVD method, or the coating method. Specifically, the inter-layer dielectric film 305 is formed to fill the space between the stacked films processed into the plate-like shape and to be thicker than the upper surface of the N-type semiconductor layer 304. Thereafter, the upper surface of the inter-layer dielectric film 305 is planarized by the CMP method with the N-type semiconductor layer 304 as a stopper.

Next, as shown in FIGS. 13C and 14C, a hafnia film 306 to be the variable resistive layer, a tantalum nitride film 307 to be the upper electrode of the variable resistive layer, and a P-type semiconductor layer 308 that sandwiches the variable resistive layer from the upper side and is composed of a B-doped polysilicon film are formed in order on the upper surfaces of the N-type semiconductor layer 304 and the inter-layer dielectric film 305 with the thickness of 10 nm, 10 nm, and 50 nm, respectively, for example, by the LPCVD method.

Furthermore, a titanium film 309 for forming titanium silicide, a titanium nitride film 310 as the barrier metal film, a tungsten film 311 to be the word line, a titanium nitride film 312 as the barrier metal film, a titanium film 313 for forming titanium silicide, and a P-type semiconductor layer 314 that sandwiches the variable resistive layer from the lower side and is composed of a B-doped polysilicon film are formed in order on the P-type semiconductor layer 308 with the thickness of 5 nm, 5 nm, 70 nm, 5 nm, 5 nm, and 50 nm, respectively, by the sputtering method. When the P-type semiconductor layers 308 and 314 are activated, the titanium films 309 and 313 react with the P-type semiconductor layers 308 and 314, respectively, to form titanium silicide.

Thereafter, as shown in FIGS. 13D and 14D, a stacked film from the P-type semiconductor layer 314 to the tantalum nitride film 307 is collectively processed into a plate-like shape by the known lithography technique and RIE method. At this time, the stacked film is processed into the plate-like shape to extend in the X direction that intersects with (in this example, orthogonal to) the Y direction. Whereby, the tungsten film 311 becomes the word line extending in the X direction.

Then, an inter-layer dielectric film 315 is formed to fill a space between the stacked films processed into the plate-like shape and to be thicker than the upper surface of the P-type semiconductor layer 314 by the film-forming method such as the PECVD method, the LPCVD method, or the coating method. Thereafter, the upper surface of the inter-layer dielectric film 315 is planarized by the CMP method with the P-type semiconductor layer 314 as a stopper.

With the above process, the N-type semiconductor layer 304 is cut only in the process same as the bit line (the tungsten film 301), so that the N-type semiconductor layer 304 becomes a shape extending in the Y direction. Moreover, the P-type semiconductor layer 308 is cut only in the process same as the word line (the tungsten film 311), so that the P-type semiconductor layer 308 becomes a shape extending in the X direction. Furthermore, the hafnia film 306 that is the variable resistive layer between the N-type semiconductor layer 304 and the P-type semiconductor layer 308 is kept in a state of not being processed at the time of processing the word line and the bit line. Consequently, the memory cell of a first layer in which the variable resistive layer is sandwiched by the N-type and P-type semiconductor layers 304 and 308 is formed at the intersection position of the bit line (the tungsten film 301) and the word line (the tungsten film 311).

Next, as shown in FIGS. 13E and 14E, a hafnia film 316 to be the variable resistive layer and a tantalum nitride film 317 to be the upper electrode are formed in order on the entire surface of the P-type semiconductor layer 314 with the thickness of 10 nm by the sputtering method. Moreover, an N-type semiconductor layer 318 that sandwiches the variable resistive layer from the upper side and is composed of a P-doped polysilicon film is formed with the thickness of 50 nm by the LPCVD method.

Thereafter, a titanium film 319 for forming titanium silicide, a titanium nitride film 320 as the barrier metal film, a tungsten film 321 to be the bit line, a titanium nitride film 322 as the barrier metal, a titanium film 323 for forming titanium silicide, and an N-type semiconductor layer 324 that sandwiches the variable resistive layer from the lower side and is composed of a P-doped polysilicon film are formed in order on the N-type semiconductor layer 318 with the thickness of 5 nm, 5 nm, 70 nm, 5 nm, 5 nm, and 50 nm, respectively, by the sputtering method. When the N-type semiconductor layers 318 and 324 are activated, the titanium films 319 and 323 react with the N-type semiconductor layers 318 and 324, respectively, to form titanium silicide.

Then, as shown in FIGS. 13F and 14F, a stacked film from the N-type semiconductor layer 324 to the tantalum nitride film 317 is collectively processed into a plate-like shape by the known lithography technique and RIE method. At this time, the stacked film is processed into the plate-like shape to extend in the Y direction. Whereby, the tungsten film 321 becomes the bit line extending in the second direction.

Then, an inter-layer dielectric film 325 is formed to fill a space between the stacked films processed into the plate-like shape and to be thicker than the upper surface of the N-type semiconductor layer 324 by the film-forming method such as the PECVD method, the LPCVD method, or the coating method. Thereafter, the upper surface of the inter-layer dielectric film 325 is planarized by the CMP method with the N-type semiconductor layer 324 as a stopper.

With the above process, the P-type semiconductor layer 314 is cut only in the process same as the word line (the tungsten film 311), so that the P-type semiconductor layer 314 becomes a shape extending in the X direction. Moreover, the N-type semiconductor layer 318 is cut only in the process same as the bit line (the tungsten film 321), so that the N-type semiconductor layer 318 becomes a shape extending in the Y direction. Furthermore, the hafnia film 316 that is the variable resistive layer between the P-type semiconductor layer 314 and the N-type semiconductor layer 318 is kept in a state of not being processed at the time of processing the bit line and the word line. Consequently, the memory cell of a second layer in which the variable resistive layer is sandwiched by the P-type and N-type semiconductor layers 314 and 318 is formed at the intersection position of the word line (the tungsten film 311) and the bit line (the tungsten film 321).

Thereafter, the similar process is repeated to realize a three-dimensionally stacked memory structure. When a memory layer of an uppermost layer is formed, for example, in FIGS. 13E and 14E, a stacked film from the tungsten film 321 to the tantalum nitride film 317 is collectively processed into a plate-like shape extending in the Y direction by the lithography technique and the RIE method after forming the tungsten film 321 to be the bit line. Then, the inter-layer dielectric film 325 is filled between the processed stacked films and the CMP process is performed with the tungsten film 321 as the stopper film, and the process ends. With the above process, the nonvolatile memory device that includes a memory layer having a structure in which the variable resistive element is sandwiched by semiconductor layers having different polarities at each intersection position of the first and second wires can be obtained.

In the above explanation, the hafnia film is used as the variable resistive film, however, any material of which resistance state changes by a voltage applied to both sides and which is an insulator before the forming process can be used. As such a material, for example, at least one material selected from the group consisting of NbOₓ, Cr-doped SrTiO₃₋ₓ, ZrOₓ, NiOₓ, Ti-doped NiOₓ, ZnOₓ, TiOₓ, TiOₓN_{y}, CuOₓ, GdOₓ, CuTeₓ, ZnMnₓO_{y}, and ZnFeₓO_{y} can be used. As described above, as the variable resistive layer in the third embodiment, only the material that is an insulator before the forming process can be used. This is because, as described above, when the variable resistive layer is composed of a conductor, the wires mutually cause a short circuit because the variable resistive layer is not etched.

Moreover, in the above explanation, the tantalum nitride is used as the MIM electrode material, however, any material that does not hinder the variable resistance characteristics thereof by reacting with the variable resistive material or a heater material can be used. As such a material, for example, titanium nitride, titanium aluminum nitride, tungsten nitride, titanium nitride silicide, tantalum carbide, titanium silicide, tungsten silicide, cobalt silicide, nickel silicide, tantalum nitride silicide, nickel platinum silicide, platinum, ruthenium, platinum rhodium, and iridium can be used.

According to the third embodiment, when the variable resistive layer before the forming process is an insulator, the variable resistive layer needs not be processed, so that the thickness of the stacked film that needs to be processed when forming the memory cell can be made lower. Thus, the effect of further making the processing of the stacked layer structure easy can be obtained in addition to the effects in the first and second embodiments.

In the first to third embodiments, explanation is given for the specific configuration of the nonvolatile memory device having the structure shown in FIG. 1 and the manufacturing method thereof, however, the present invention is not limited these embodiments. For example, the nonvolatile memory device can be configured by appropriately combining materials described in the embodiments or materials having characteristics explained in the embodiments and using it. In this case also, the effects explained in the above embodiments, such as that the stable operation can be expected because the breakdown of a diode due to the concentration of the electric field in the I layer of the diode does not occur and that a tiny resistive random access memory can be manufactured relatively easily because the aspect ratio in processing becomes small due to the simplification of the stacked layer structure and the pattern collapse or the like is hard to occur, can be obtained.

Moreover, embodiments of the present invention can be applied to the following manufacturing method of the nonvolatile memory device. That is, for forming a memory cell that is sandwiched between a first wire and a second wire that are orthogonal to each other, the first wire is first formed, then a stacked film including a P-type semiconductor layer, a variable resistive layer, and an N-type semiconductor layer is formed on the first wire, the stacked film is etched into a columnar shape so that the memory cell is formed on the first wire, an inter-layer dielectric film is formed to fill a space between etched memory cells and to be thicker than the upper surfaces of the memory cells, thereafter a trench is formed in the inter-layer dielectric film in a direction intersecting with the first wire so that the upper surfaces of the memory cells are exposed, and the second wire is formed in the trench, thereby forming the memory cell having a columnar structure at an intersection position of the first wire and the second wire.

As explained above, according to the present embodiments of the present invention, in the nonvolatile memory device including nonvolatile storage elements such as phase-change memories and resistive random access memories arranged at intersections of a plurality of first wires that extends in parallel with the first direction and a plurality of second wires that extends in parallel with the second direction together with rectifier elements, the height can be suppressed compared with the conventional technology.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile memory device comprising:
a first wire that extends in a first direction;
a second wire that is formed at a height different from the first wire and extends in a second direction; and
a nonvolatile memory cell that is arranged to be sandwiched between the first wire and the second wire at a position at which the first wire and the second wire intersect with each other, wherein
the nonvolatile memory cell includes a structure in which a nonvolatile storage element is sandwiched by semiconductor layers having different polarities.

2. The nonvolatile memory device according to claim 1, wherein each of the semiconductor layers is such that a Schottky junction is formed at an interface on a side of the nonvolatile storage element and an ohmic contact is formed at an interface on a side of the first or the second wire.

3. The nonvolatile memory device according to claim 1, wherein at least one of the semiconductor layers having different polarities has a shape same as the first or the second wire.

4. The nonvolatile memory device according to claim 1, wherein the nonvolatile storage element includes a variable resistive layer that is formed of a semiconductor or an insulator.

5. The nonvolatile memory device according to claim 4, wherein the variable resistive layer is formed of at least one material selected from the group consisting of C, NbOₓ, Ti-doped NiOₓ, Cr-doped SrTiO₃₋ₓ, PrₓCa_{y}MnO_{z}, ZrOₓ, NiOₓ, ZnOₓ, TiOₓ, TiOₓN_{y}, CuOₓ, GdOₓ, CuTeₓ, HfOₓ, ZnMnₓO_{y}, ZnFeₓO_{y}, GeSbₓTe_{y} (hereinafter, GST), N-doped GST, O-doped GST, GeSb, and InGeₓTe_{y}.

6. The nonvolatile memory device according to claim 4, wherein the nonvolatile storage element includes a structure in which the variable resistive layer is sandwiched from above and below by electrode layers.

7. The nonvolatile memory device according to claim 6, wherein each of the electrode layers is formed of at least one material selected from the group consisting of titanium nitride, tungsten nitride, titanium aluminum nitride, tantalum nitride, titanium nitride silicide, tantalum carbide, titanium silicide, tungsten silicide, cobalt silicide, nickel silicide, tantalum nitride silicide, nickel platinum silicide, platinum, ruthenium, platinum rhodium, and iridium.

8. The nonvolatile memory device according to claim 1, wherein
the first wire, the nonvolatile memory cell, and the second wire are stacked in a height direction, and
one of the first wire and the second wire is shared between the nonvolatile memory cells that are adjacent to each other in an up and down direction.

9. A method of manufacturing a nonvolatile memory device comprising:
forming a stacked film that includes a structure in which a nonvolatile memory layer is sandwiched by semiconductor layers having different polarities above a substrate; and
etching the stacked film by using a dry etching method so that a memory cell array, in which memory cells each including a structure in which the nonvolatile memory layer is sandwiched by the semiconductor layers having different polarities are two-dimensionally arranged at respective intersection positions of a plurality of first wires that extends in a predetermined direction and a plurality of second wires that extends in a direction intersecting with the predetermined direction, is formed.

10. The method according to claim 9, wherein
the forming the stacked film includes
stacking a first conductive layer to be the first wires, a first semiconductor layer, the nonvolatile memory layer, and a cap film including a conductive material in order,
etching the cap film, the nonvolatile memory layer, the first semiconductor layer, and the first conductive layer, in a plate-like shape extending in the predetermined direction,
filling with an inter-layer dielectric film, a space between structures etched in the plate-like shape, and
forming a second semiconductor layer having a polarity opposite to the first semiconductor layer and a second conductive layer to be the second wires above the inter-layer dielectric film and the cap film, and
the etching the stacked film includes
etching the second conductive layer, the second semiconductor layer, and the cap film and the nonvolatile memory layer in the etched structures which are lower than the second conductive layer, in a plate-like shape extending in a direction substantially vertical to the etched structures which are lower than the second conductive layer.

11. The method according to claim 10, wherein
the filling with the inter-layer dielectric film includes
forming the inter-layer dielectric film over the etched structures to be thicker than an upper surface of the cap film, and thereafter
removing the inter-layer dielectric film formed above the upper surface of the cap film with the cap film as a stopper.

12. The method according to claim 10, wherein
a process is performed at least once after the filling with the inter-layer dielectric film, the process including
forming, above the inter-layer dielectric film of a lower portion and the cap film of a lower portion, the second semiconductor layer of a lower portion, the second conductive layer of a lower portion, a first semiconductor layer of an upper portion having a polarity same as the second semiconductor layer of the lower portion, a nonvolatile memory layer of an upper portion, and a cap film of an upper portion,
etching the cap film of the upper portion, the nonvolatile memory layer of the upper portion, the first semiconductor layer of the upper portion, the second conductive layer of the lower portion, the second semiconductor layer of the lower portion, and the cap film and the nonvolatile memory layer in the etched structures which are lower than the second conductive layer, in a plate-like shape extending in a direction substantially vertical to the etched structures which are lower than the second conductive layer, to form structures of an upper layer, and
filling with an inter-layer dielectric film of an upper layer, a space between the structures of the upper layer.

13. The method according to claim 9, wherein
the forming the stacked film includes
stacking a first conductive layer to be the first wires, a first semiconductor layer, the nonvolatile memory layer, and a second semiconductor layer having a polarity opposite to the first semiconductor layer in order,
the etching the stacked film includes
etching the second semiconductor layer, the nonvolatile memory layer, the first semiconductor layer, and the first conductive layer, in a plate-like shape extending in the predetermined direction,
filling with an inter-layer dielectric film, a space between structures etched in the plate-like shape,
forming a second conductive layer to be the second wires above the inter-layer dielectric film and the second semiconductor layer, and
etching the second conductive layer, and the second semiconductor layer and the nonvolatile memory layer in the etched structures which are lower than the second conductive layer, in a plate-like shape extending in a direction substantially vertical to the etched structures which are lower than the second conductive layer.

14. The method according to claim 13, wherein
the filling with the inter-layer dielectric film includes
forming the inter-layer dielectric film over the etched structures to be thicker than an upper surface of the second semiconductor layer, and thereafter
removing the inter-layer dielectric film formed above the upper surface of the second semiconductor layer with the second semiconductor layer as a stopper.

15. The method according to claim 13, wherein
a process is performed at least once after the filling with the inter-layer dielectric film, the process including
forming, above the inter-layer dielectric film of a lower portion and the second semiconductor layer of a lower portion, the second conductive layer of a lower portion, a first semiconductor layer of an upper portion having a polarity same as the second semiconductor layer of the lower portion, a nonvolatile memory layer of an upper portion, and a second semiconductor layer of an upper portion having a polarity opposite to the first semiconductor layer of the upper portion,
etching the second semiconductor layer of the upper portion, the nonvolatile memory layer of the upper portion, the first semiconductor layer of the upper portion, the second conductive layer of the lower portion, and the second semiconductor layer and the nonvolatile memory layer in the etched structures which are lower than the second conductive layer, in a plate-like shape extending in a direction substantially vertical to the etched structures which are lower than the second conductive layer, to form structures of an upper layer, and
filling with an inter-layer dielectric film of an upper layer, a space between the structures of the upper layer.

16. The method according to claim 9, wherein
the forming the stacked film includes
stacking a first conductive layer to be the first wires and a first semiconductor layer in order,
etching the first semiconductor layer and the first conductive layer in a plate-like shape extending in the predetermined direction,
filling with an inter-layer dielectric film, a space between structures etched in the plate-like shape, and
stacking the nonvolatile memory layer, a second semiconductor layer having a polarity opposite to the first semiconductor layer, and a second conductive layer to be the second wires in order above the inter-layer dielectric film and the first semiconductor layer, and
the etching the stacked film includes
etching the second conductive layer and the second semiconductor layer in a plate-like shape extending in a direction substantially vertical to the etched structures which are lower than the second conductive layer.

17. The method according to claim 16, wherein
the filling with the inter-layer dielectric film includes
forming the inter-layer dielectric film over the etched structures to be thicker than an upper surface of the first semiconductor layer, and thereafter
removing the inter-layer dielectric film formed above the upper surface of the first semiconductor layer with the first semiconductor layer as a stopper.

18. The method according to claim 16, wherein the nonvolatile memory layer includes a variable resistive material that is an insulator at a time of forming the nonvolatile memory layer.

19. The method according to claim 16, wherein
a process is performed at least once after the filling with the inter-layer dielectric film, the process including
forming, above the inter-layer dielectric film of a lower portion and the first semiconductor layer of a lower portion, the nonvolatile memory layer of a lower portion, the second semiconductor layer of a lower portion, the second conductive layer of a lower portion, and a first semiconductor layer of an upper portion having a polarity same as the second semiconductor layer of the lower portion,
etching the first semiconductor layer of the upper portion, the second conductive layer of the lower portion, and the second semiconductor layer of the lower portion, in a plate-like shape extending in a direction substantially vertical to the etched structures which are lower than the second conductive layer, to form structures of an upper layer, and
filling with an inter-layer dielectric film of an upper layer, a space between the structures of the upper layer.

20. The method according to claim 9, wherein
the forming the stacked film includes
forming a stacked film that includes a first conductive semiconductor layer, the nonvolatile memory layer, and a second conductive semiconductor layer above a first insulating film in which the first wires extending in the predetermined direction are formed, and
the etching the stacked film includes
etching the stacked film in a columnar shape so that the stacked film is positioned above the first wires,
forming a second insulating film to fill a space between the stacked films etched in the columnar shape and to be higher than an upper surface of the stacked film,
forming a wiring trenches in the second insulating film so that the wiring trenches extend in a direction intersecting with the predetermined direction and are connected to the stacked film, and
forming the second wires in the wiring trenches.
